(19) United States
(12) Patent Application Publication
(10) Pub. No.: US 2026/0314160 A1
(43) Pub. Date: Oct. 8, 2026

(54) METHOD FOR MANUFACTURING QUANTUM DOT, QUANTUM DOT, AND ELECTRONIC APPARATUS INCLUDING THE QUANTUM DOT

(71) Applicant: Samsung Display Co., Ltd., Yongin-si (KR)

(72) Inventors: Bitna YOON, Yongin-si (KR); SUNGJAE KIM, Yongin-si (KR); Youngsik KIM, Yongin-si (KR); Hongrae KIM, Yongin-si (KR); JUO NAM, Yongin-si (KR); SEUNG-WON PARK, Yongin-si (KR); TAEKJOON LEE, Yongin-si (KR); JUNEHYUK JUNG, Yongin-si (KR)

(21) Appl. No.: 19/454,821

(22) Filed: Jan. 21, 2026

(30) Foreign Application Priority Data
Apr. 8, 2025 (KR) 10-2025-0045083

(51) Int. Cl. H10K 50/115; C09K 11/56; C09K 11/58; C09K 11/62; H10K 85/30; H10K 102/00

(52) U.S. Cl. CPC H10K 50/115; C09K 11/565; C09K 11/58; C09K 11/62; H10K 85/326; H10K 2102/331

(57) ABSTRACT

A method for manufacturing a quantum dot including a core, which includes a multi-component system compound including Cu, In, Ga, and S, and a shell covering the core is provided. The method may include preparing a first mixture including a copper precursor and a metal catalyst, providing a first sulfur precursor to the first mixture to form a preliminary core, providing a second mixture including a gallium precursor and an indium precursor to the preliminary core at a first temperature, forming a core at a second temperature higher than the first temperature, and forming a shell covering the core. The metal catalyst may include at least one first component selected from among Ag, Au, Li, Na, and K.

### CROSS-REFERENCE TO RELATED APPLICATION

The present application claims priority to and the benefit of Korean Patent Application No. 10-2025-0045083, filed on Apr. 8, 2025, in the Korean Intellectual Property Office, the entire content of which is incorporated herein by reference.

### BACKGROUND

### 1. Field

One or more embodiments of the present disclosure herein relate to quantum dots, for example, to a quantum dot manufacturing method that includes providing a metal catalyst, a quantum dot manufactured by the method, and an electronic apparatus including the quantum dot.

### 2. Description of Related Art

Quantum dots are semiconductor nanocrystals whose energy band gaps may be adjusted by controlling their size and composition, enabling emission of light at various wavelengths. Due to these properties, quantum dots are utilized as emission materials in in light-emitting elements, electronic apparatuses, and/or like. Recent development efforts have focused on improving color reproducibility in light-emitting elements, electronic apparatuses, and/or like, incorporating the quantum dots. Quantum dots may each include a core and a shell, and the core is often formed utilizing a metal precursor. The characteristics of the resulting quantum dots may vary depending on the method utilized to provide the metal precursor.

### SUMMARY

One or more aspects of embodiments of the present disclosure are directed toward a quantum dot manufacturing method that exhibits excellent or suitable processibility.

One or more aspects of embodiments of the present disclosure are directed toward a quantum dot that exhibits excellent or suitable emission efficiency and an electronic apparatus including the same.

Additional aspects will be set forth in part in the description which follows and, in part, will be apparent from the description, or may be learned by practice of the presented embodiments.

According to one or more embodiments of the present disclosure, there is provided a method for manufacturing a quantum dot including a core and a shell covering the core, the core including a multi-component system compound which includes Cu, In, Ga, and S, and the method including: preparing a first mixture including a copper precursor and a metal catalyst; providing a first sulfur precursor to the first mixture to form a preliminary core; providing a second mixture including a gallium precursor and an indium precursor to the preliminary core at a first temperature; forming the core at a second temperature higher than the first temperature; and forming the shell covering the core, wherein the metal catalyst includes at least one first component selected from among Ag, Au, Li, Na, and K.

In one or more embodiments, the metal catalyst may further include a second component chemically bonded to the first component, and the second component may include at least one selected from among a halogen element and oleate.

In one or more embodiments, the core may include the first component in an amount of less than about 3 mol % with respect to the total moles of the core before the forming of the shell.

In one or more embodiments, the second temperature may be about 230° C. to about 330° C.

In one or more embodiments, the forming of the shell may include providing a zinc precursor and a second sulfur precursor to the core, and forming the shell at a temperature of about 200° C. or more.

In one or more embodiments, moles of a first core component may be about 0.2 times to about 0.5 times moles of a second core component in the quantum dot, and the first core component may be the Cu, and the second core component may be the In and the Ga.

In one or more embodiments, moles of the Ga may be about 0.05 times to about 20 times moles of the In.

In one or more embodiments, the shell may include ZnS, and moles of the Zn of the shell may be about 1 time to about 5 times moles of the Cu of the core.

In one or more embodiments, the quantum dot has a peak emission wavelength in a wavelength region of about 520 nanometers (nm) to about 640 nm, a full width at half maximum (FWHM) of about 41 nm or less, and a quantum yield of about 85% or more.

In one or more embodiments, the copper precursor may include at least one selected from among copper halide, copper acetate, and copper nitrate, the first sulfur precursor may include at least one selected from among sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis (trimethylsilyl) sulfide, the indium precursor may include at least one selected from among indium (III) acetylacetonate, indium (III) bromide, indium (III) chloride, indium (III) fluoride, indium (III) iodide, indium (III) acetate, trimethyl indium, alkyl indium, aryl indium, indium (III) myristate, indium (III) myristate acetate, and indium (III) di-myristate acetate, the gallium precursor may include at least one selected from among gallium nitride, gallium phosphide, gallium (III) chloride, gallium (III) acetylacetonate, gallium (III) bromide, gallium (III) chloride, gallium (III) fluoride, gallium (III) iodide, gallium (III) nitrate hydrate, gallium (III) sulfate, and gallium (III) sulfate hydrate, and the first mixture and the second mixture may each further include at least one selected from among oleylamine, 1-octadecene, octadecane, methanethiol, ethanethiol, propanethiol, butanethiol, pentanethiol, hexanethiol, octanethiol, hexadecanethiol, benzylthiol, methane amine (methylamine), ethane amine (ethylamine), propane amine (propylamine), butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, and trioctyl phosphine oxide.

In one or more embodiments, the core may have a peak emission wavelength in a wavelength region of about 520 nm to about 640 nm, a full width at half maximum of about 40 nm or less, and a quantum yield of about 10% or more.

According to one or more embodiments of the present disclosure, a quantum dot includes: a core including a multi-component system compound containing Cu, In, Ga, and S; and a shell covering the core, wherein moles of a first core component are about 0.2 times to about 0.5 times moles of a second core component, and the first core component is the Cu and the second core component is the In and the Ga.

In one or more embodiments, the core may be divided into an outer region and a central region spaced and/or apart (e.g., spaced apart or separated) from the shell with the outer region therebetween, and the outer region may be arranged between the central region and the shell, and wherein a content (e.g., amount) of the In may increase toward the central region from the outer region, and a content (e.g., amount) of the Ga may increase from the central region toward the outer region.

In one or more embodiments, moles of the Ga may be about 0.05 times to about 20 times moles of the In.

In one or more embodiments, the quantum dot may have a peak emission wavelength in a wavelength region of about 520 nm to about 640 nm, a full width at half maximum (FWHM) of about 41 nm or less, and a quantum yield of about 85% or more, and the core may have a diameter of about 2 nm to about 10 nm, and the shell may have a thickness of about 0.02 nm to about 10 nm.

In one or more embodiments, the shell may include ZnS, and moles of the Zn of the shell may be about 1 time to about 5 times the moles of the Cu of the core.

According to one or more embodiments of the present disclosure, an electronic apparatus includes a display module including a light-emitting element configured to emit source light, and an optical layer on (e.g., arranged on) the display module and configured to transmit the source light or convert a wavelength of the source light, the light-emitting element and/or the optical layer includes a quantum dot, the quantum dot includes a core including a multi-component system compound which includes Cu, In, Ga, and S, and a shell covering the core, moles of a first core component are about 0.2 times to about 0.5 times moles of a second core component, and the first core component is the Cu and the second core component is the In and the Ga.

In one or more embodiments, the quantum dot may have a peak emission wavelength in a wavelength region of about 520 nm to about 640 nm, a full width at half maximum (FWHM) of about 41 nm or less, and a quantum yield of about 85% or more.

In one or more embodiments, the optical layer may include a first light control unit configured to convert the source light and a second light control unit configured to transmit the source light, and the first light control unit may include the quantum dot.

In one or more embodiments, the light-emitting element may include a first electrode, a second electrode on (e.g., arranged on) the first electrode, an emission layer between (e.g., arranged between) the first electrode and the second electrode and including the quantum dot, a hole transport region between (e.g., arranged between) the first electrode and the second electrode, and an electron transport region between (e.g., arranged between) the first electrode and the second electrode and spaced and/or apart (e.g., spaced apart or separated) from the hole transport region, and the emission layer may be between (e.g. arranged between) the hole transport region and the electron transport region.

It should be understood that the disclosed quantum dot manufacturing methods, quantum dots, and electronic apparatuses may be implemented in various forms and combined in different ways without departing from the spirit of the inventive concept. For example, the order of introducing precursors, the temperature ranges for core and shell formation, and the composition ratios of Cu, In, and Ga may be varied, substituted, or enhanced to achieve substantially similar technical effects, such as improved processability, enhanced emission efficiency, and stable optical performance. Likewise, the disclosed quantum dots may be incorporated into various electronic apparatuses in configurations other than those explicitly described.

### BRIEF DESCRIPTION OF DRAWINGS

The accompanying drawings are included to provide a further understanding of the present disclosure, and are incorporated in and constitute a part of this disclosure. The drawings illustrate embodiments of the disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a perspective view illustrating an electronic apparatus according to one or more embodiments of the present disclosure;

FIG. 2 is a block diagram of an electronic apparatus according to one or more embodiments of the present disclosure;

FIG. 3 is a view illustrating electronic apparatuses according to one or more embodiments of the present disclosure;

FIG. 4 is an exploded perspective view illustrating an electronic apparatus according to one or more embodiments of the present disclosure;

FIG. 5 is a cross-sectional view illustrating a portion taken along the line I-I′ in FIG. 4 according to one or more embodiments of the present disclosure;

FIG. 6 is a plan view illustrating a portion of an electronic apparatus according to one or more embodiments of the present disclosure;

FIG. 7A is a cross-sectional view illustrating a portion of an electronic apparatus according to one or more embodiments of the present disclosure;

FIG. 7B is a cross-sectional view illustrating a portion of an electronic apparatus according to one or more embodiments of the present disclosure;

FIG. 7C is a cross-sectional view illustrating a portion of an electronic apparatus according to one or more embodiments of the present disclosure;

FIG. 7D is a cross-sectional view illustrating a portion of an electronic apparatus according to one or more embodiments of the present disclosure;

FIG. 8A is a cross-sectional view illustrating a portion of an electronic apparatus according to one or more embodiments of the present disclosure;

FIG. 8B is a cross-sectional view illustrating a portion of an electronic apparatus according to one or more embodiments of the present disclosure;

FIG. 8C is a cross-sectional view illustrating a portion of an electronic apparatus according to one or more embodiments of the present disclosure;

FIG. 8D is a cross-sectional view illustrating a portion of an electronic apparatus according to one or more embodiments of the present disclosure;

FIG. 9 is a view schematically illustrating a quantum dot according to one or more embodiments of the present disclosure;

FIG. 10 is a flow chart showing a method for manufacturing a quantum dot according to one or more embodiments of the present disclosure;

FIG. 11 is a diagram schematically showing steps (e.g., acts or tasks) for manufacturing a quantum dot according to one or more embodiments of the present disclosure;

FIG. 12 is a graph showing photoluminescence (PL) versus wavelengths of a quantum dot according to one or more embodiments of the present disclosure;

FIG. 13 is a captured image of a core in a quantum dot according to one or more embodiments of the present disclosure;

FIG. 14A is a captured image of a core in a quantum dot according to one or more embodiments of the present disclosure;

FIG. 14B is a captured image of a core in a quantum dot according to one or more embodiments of the present disclosure;

FIG. 14C is a captured image of a core in a quantum dot according to one or more embodiments of the present disclosure;

FIG. 15 is a graph showing a composition of a quantum dot according to one or more embodiments of the present disclosure; and

FIG. 16 is a graph showing a composition of a quantum dot according to one or more embodiments of the present disclosure.

### DETAILED DESCRIPTION

The disclosure may have one or more suitable modifications and may be embodied in different forms, and example embodiments will be explained in more detail with reference to the accompany drawings. It should be understood, however, that it is not intended to limit the present disclosure to the particular forms disclosed, but rather, is intended to include all modifications, equivalents, and alternatives falling within the spirit and scope of the present disclosure.

In this disclosure, it will be understood that if (e.g., when) an element (or a region, a layer, a portion, and/or the like) is referred to as being “on”, “connected to” or “coupled to” another element, it may be directly arranged on, connected to, or coupled to the other element, or one or more other elements may be arranged therebetween. In contrast, “directly on” may refer to that there are no additional intervening elements or layers between the element or layer and the other element or layer. In addition, if (e.g., when) a layer, a film, a region, a plate, and/or the like is referred to as being “under” or “below” another part, it may be “directly under” the other part, or one or more intervening layers may be present therebetween. Also, if (e.g., when) an element is referred to as being arranged “on” another element, it may be arranged under the other element.

Like reference numerals or symbols refer to like elements throughout the disclosure, and duplicative descriptions thereof may not be provided for conciseness.

In the drawings, the thickness, ratio, and size of elements may be exaggerated or reduced for effectively describing the technical contents. As used herein, the term “and/or” or “or” or “/” may include any and all combinations of one or more of the associated listed elements.

It will be understood that, although the terms “first”, “second”, and/or the like may be used herein to describe one or more suitable elements, the elements are not to be limited by these terms. These terms are only used to distinguish one element, component, region, layer, or section from another element, component, region, layer, or section. For instance, a first element, component, region, layer, or section discussed herein could be termed a second element, component, region, layer, or section without departing from the scope and teachings of the disclosure. Similarly, a second element, component, region, layer, or section could be termed a first element, component, region, layer, or section. In this disclosure, the singular expressions “a”, “an” and “the” are intended to include the plural forms as well, unless the context clearly indicates otherwise. Further, the use of “may” when describing embodiments of the present disclosure refers to “one or more embodiments of the present disclosure.”

In addition, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprise(s)/include(s)/has(have)” and/or “comprising/including/having”, if (e.g., when) used in this disclosure, specify the presence of stated features, numbers, steps, operations, elements, components, or combinations thereof, but do not preclude the possibility of the presence or addition of one or more other features, numbers, steps, operations, elements, components, and/or combinations thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

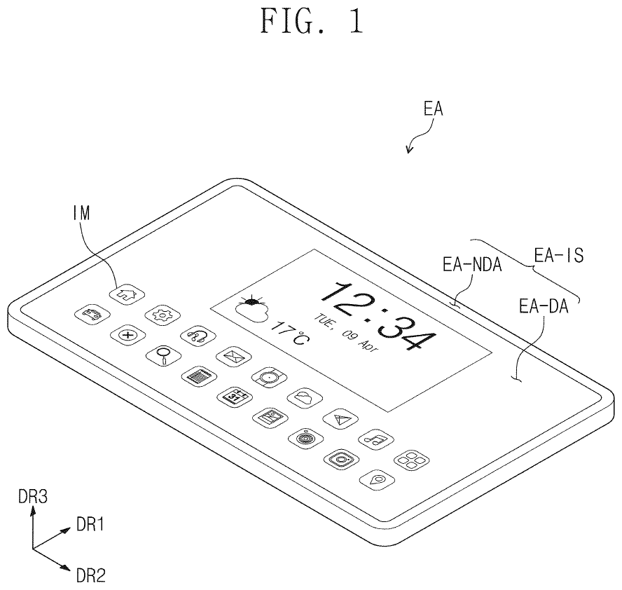

Hereinafter, example embodiments of the present disclosure are described with reference to the drawings. FIG. 1 is a perspective view illustrating an electronic apparatus according to one or more embodiments of the present disclosure.

An electronic apparatus EA according to one or more embodiments, illustrated in FIG. 1, may be activated in response to an electrical signal. For example, the electronic apparatus EA may be a personal computer, a laptop computer, a personal digital assistant, a game console, a portable electronic apparatus, a television, a monitor, an outdoor billboard, a car navigation system, or a wearable apparatus, but embodiments of the present disclosure are not limited thereto. FIG. 1 illustrates a television as an example of the electronic apparatus EA.

The electronic apparatus EA may provide an image IM to a user through a display surface EA-IS. The display surface EA-IS may be parallel to a plane defined by a first direction axis DR1 and a second direction axis DR2. The electronic apparatus EA may display the image IM toward a direction of a third direction axis DR3. The image IM may include a still image as well as a dynamic image. FIG. 1 illustrates, in one or more embodiments, the electronic apparatus EA including a flat display surface EA-IS, but embodiments of the present disclosure are not limited thereto. For example, in one or more embodiments, the electronic apparatus EA may also include a curved display surface or a three-dimensional display surface. The three-dimensional display surface may also include a plurality of display regions indicating different directions from each other.

Directions indicated by the first to third direction axes DR1, DR2, and DR3, described in the present disclosure, are relative concepts, and thus may be changed into the other directions. In addition, the directions indicated by the first to third direction axes DR1, DR2, and DR3 may be described as first to third directions, and the same reference symbols or numerals may be used.

In the present disclosure, the first direction axis DR1 and the second direction axis DR2 are normal (e.g., perpendicular) to each other, and the third direction axis DR3 may be a normal direction of a plane defined by the first direction axis DR1 and the second direction axis DR2. A thickness direction of the electronic apparatus EA may be parallel to the third direction axis DR3. The thickness direction of the electronic apparatus EA may use the same reference numeral as the third direction axis DR3. A front surface (or top surface) and a rear surface (or bottom surface) are opposed to each other in the third direction axis DR3, and a normal direction of each of the front surface (or top surface) and the rear surface (or bottom surface) may be parallel to the third direction axis DR3. The front surface (or top surface) refers to a surface adjacent to the display surface EA-IS, and the rear surface (or bottom surface) refers to a surface spaced and/or apart (e.g., spaced apart or separated) from the display surface EA-IS. An upper side refers to a direction getting closer to the display surface EA-IS, and a lower side refers to a direction getting farther away from the display surface EA-IS.

In the present disclosure, a cross-section refers to a surface parallel to the thickness direction DR3. The plane refers to a plane which is perpendicular to the thickness direction DR3, and is parallel to the plane defined by the first direction axis DR1 and the second direction axis DR2.

In the present disclosure, the wording, “one component overlapping another component” refers to that the components overlap each other on a plane (e.g., in plan view or view from the third direction DR3). In addition, the wording, “one component overlapping another component” is not limited to an embodiment in which the components have a same area and a same shape and includes an embodiment in which the components have different areas and/or different shapes as well.

The electronic apparatus EA may detect an external input applied from the outside. The external input may include one or more suitable types (kinds) of inputs provided from the outside of the electronic apparatus EA. For example, the external input may include not only an external input applied by touch of a part of a user's body such as a user's hand, but also an external input applied in proximity to or adjacent at a set distance to the electronic apparatus EA (for example, hovering). In one or more embodiments, the external input may have one or more suitable forms such as power, pressure, temperature, and light.

The display surface EA-IS may include a display region EA-DA and a non-display region EA-NDA. The electronic apparatus EA may display the image IM through the display region EA-DA.

The display region EA-DA may be a region activated in response to an electrical signal. The display region EA-DA may be a region in which the image IM is displayed, and one or more suitable forms of external input may be detected.

In one or more embodiments, the display region EA-DA may include a flat surface defined by the first direction axis DR1 and the second direction axis DR2. In one or more embodiments, the display region EA-DA may include a curved surface bent from at least one side of the flat surface defined by the first direction axis DR1 and the second direction axis DR2. For example, in one or more embodiments, the display region EA-DA may further include curved surfaces bent from at least two sides of the flat surface defined by the first direction axis DR1 and the second direction axis DR2, and, in one or more embodiments, may include, for example, four curved surfaces respectively bent from four sides of the flat surface defined by the first direction axis DR1 and the second direction axis DR2.

The electronic apparatus EA according to one or more embodiments may be flexible. The term “flexible” refers to bendable properties and may encompass all structures from a completely foldable structure to a structure bendable at a several nanometer-scale. For example, in one or more embodiments, the electronic apparatus EA may be a rigid apparatus. In one or more embodiments, the electronic apparatus EA may be a foldable apparatus.

The non-display region EA-NDA may not be optically transparent and may have a color. The non-display region EA-NDA may be a region adjacent to the display region EA-DA. The non-display region EA-NDA may surround the display region EA-DA. Accordingly, a shape of display region EA-DA may be defined by the non-display region EA-NDA. However, the non-display region EA-NDA illustrated in FIG. 1 is an example, and the non-display region EA-NDA may be arranged adjacent to only one side of the display region EA-DA, or may not be provided. The display region EA-DA may be provided in one or more suitable shapes, but embodiments of the present disclosure are not limited thereto.

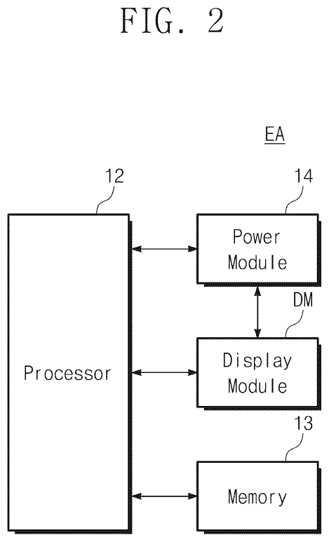

FIG. 2 is a block diagram of an electronic apparatus according to one or more embodiments of the present disclosure. Referring to FIG. 2, the electronic apparatus EA according to one or more embodiments may include a display module DM, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller. The power module 14 may include a power supply module such as a power adaptor or a battery device, and a power conversion module that converts power supplied by the power supply module to generate power needed for operations of the electronic apparatus EA.

The memory 13 may store data information needed for operations of the processor 12 and/or the display module DM. When the processor 12 executes an application stored in the memory 13, an image data signal and/or an input control signal are transmitted to the display module DM, and the display module DM may process the received signal and output image information through a display screen.

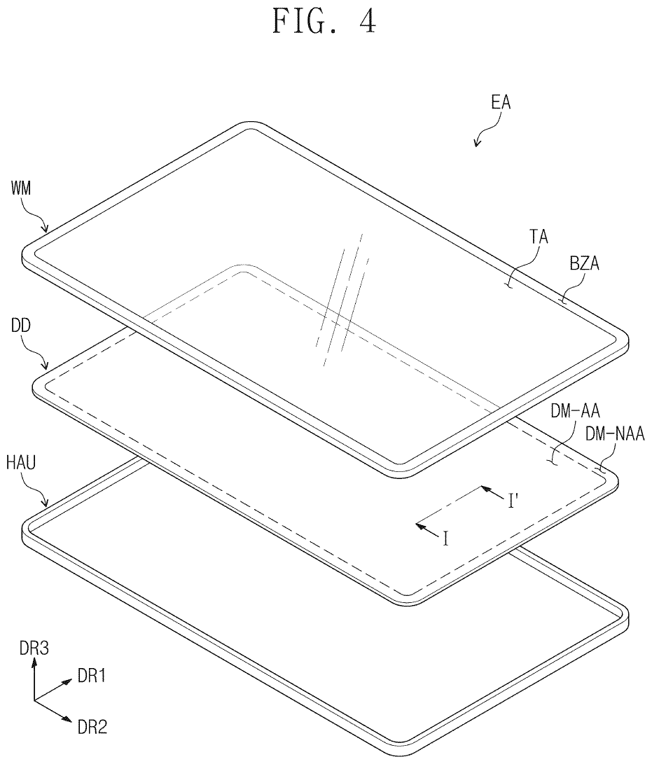

At least one of the components of the electronic apparatus EA may be included in the display module DM according to one or more embodiments. In addition, some of individual modules functionally included in one module among the components of the electronic apparatus EA may be included in a display device DD (FIG. 4), and some others may be provided separately from the display device DD (FIG. 4). For example, in one or more embodiments, the display device DD (FIG. 4) may include the display module DM, and the processor 12, the memory 13, and the power module 14 may be provided in the form of other devices within the electronic apparatus EA, rather than the display device DD (FIG. 4).

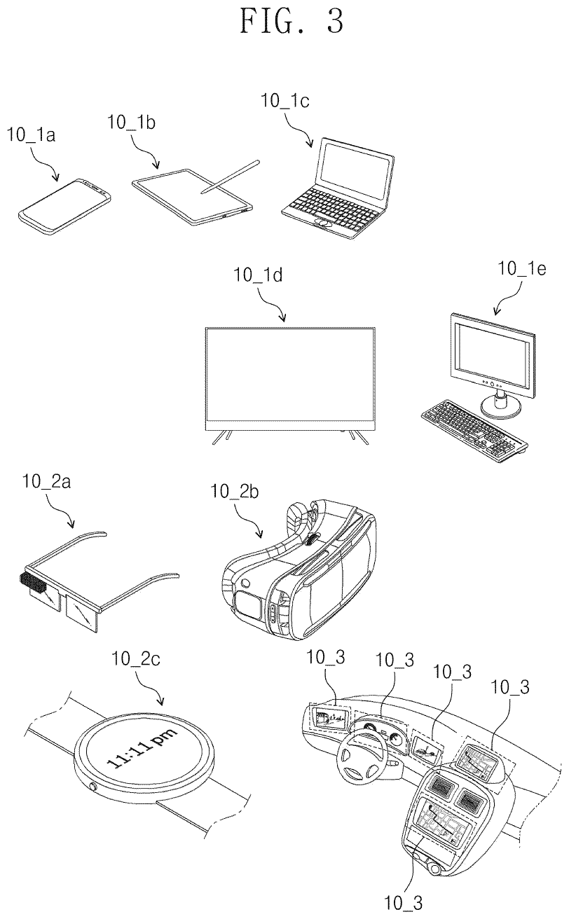

FIG. 3 shows schematic views of electronic apparatuses according to one or more embodiments of the present disclosure. Referring to FIG. 3, an electronic apparatus (e.g., the electronic apparatus EA of FIG. 2) including the display module DM (FIG. 4) according to one or more embodiments may include not only an image-displaying electronic apparatus such as a smart phone 10_1a, a tablet PC10_1b, a laptop computer 10_1c, a TV 10_1d, and a desktop monitor 10_1e, but also a wearable electronic apparatus such as smart glasses 10_2a, a head mounted display 10_2b, or a smart watch 10_2c, and a vehicular electronic apparatus 10_3 such as a center information display (CID) located on a vehicle's instrument cluster, center fascia, or dashboard, a room mirror display of the vehicle, and/or the like.

FIG. 4 is an exploded perspective view illustrating an electronic apparatus according to one or more embodiments. Referring to FIG. 4, in one or more embodiments, the electronic apparatus EA may include a display device DD. In addition, the electronic apparatus EA may further include a window member WM and a housing HAU.

The window member WM may be arranged on the display device DD. The window member WM may cover the entire exterior (e.g., entire front exterior) of the electronic apparatus EA. The window member WM include a transmissive region TA and a bezel region BZA. A front surface of the window member WM including the transmissive region TA and the bezel region BZA may correspond to a front surface of the electronic apparatus EA. The transmissive region TA may correspond to the display region EA-DA of the electronic apparatus EA illustrated in FIG. 1, and the bezel region BZA may correspond to the non-display region EA-NDA of the electronic apparatus EA illustrated in FIG. 1.

The transmissive region TA may be an optically transparent region. The bezel region BZA may be a region having relatively lower transmittance than the transmissive region TA. In one or more embodiments, the bezel region BZA may not be optically transparent and may have a color. The bezel region BZA may be adjacent to the transmissive region TA and may surround the transmissive region TA. The bezel region BZA may define a shape of the transmissive region TA. However, embodiments of the present disclosure are not limited to what is illustrated in FIG. 4, for example, in one or more embodiments, the bezel region BZA may be arranged adjacent to only one side of the transmissive region TA, and a portion thereof may not be provided.

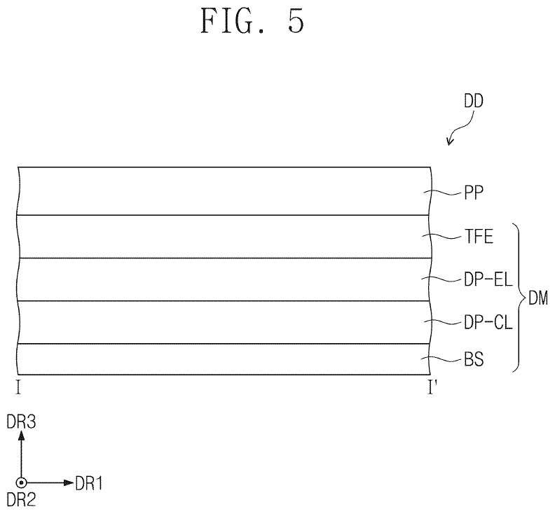

The housing HAU may include a material having relatively high rigidity. For example, in one or more embodiments, the housing HAU may include a frame and/or a plate composed of glass, plastic, or metal. The frame and/or the plate may be provided in plurality. The housing HAU may provide an accommodation space. The display device DD (e.g., display module DM, see FIG. 5) may be accommodated in the accommodation space and protected from an external impact.

The display device DD may be activated in response to an electrical signal and may provide an image IM (FIG. 1). The display device DD may be activated to display an image or video IM (FIG. 1) in the display region EA-DA (FIG. 1). An active region DM-AA and a peripheral region DM-NAA may be defined in the display device DD.

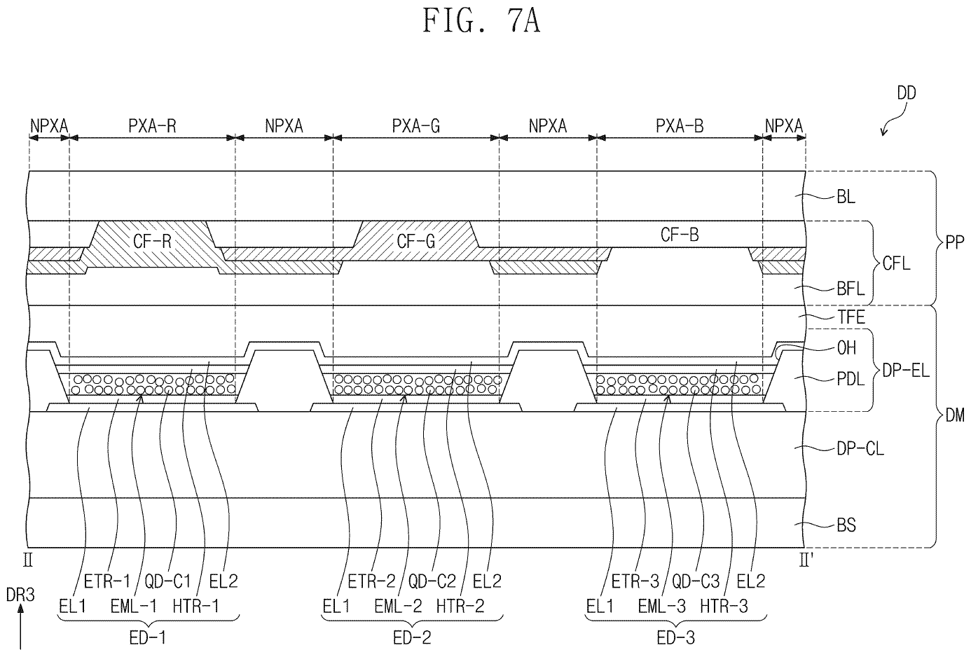

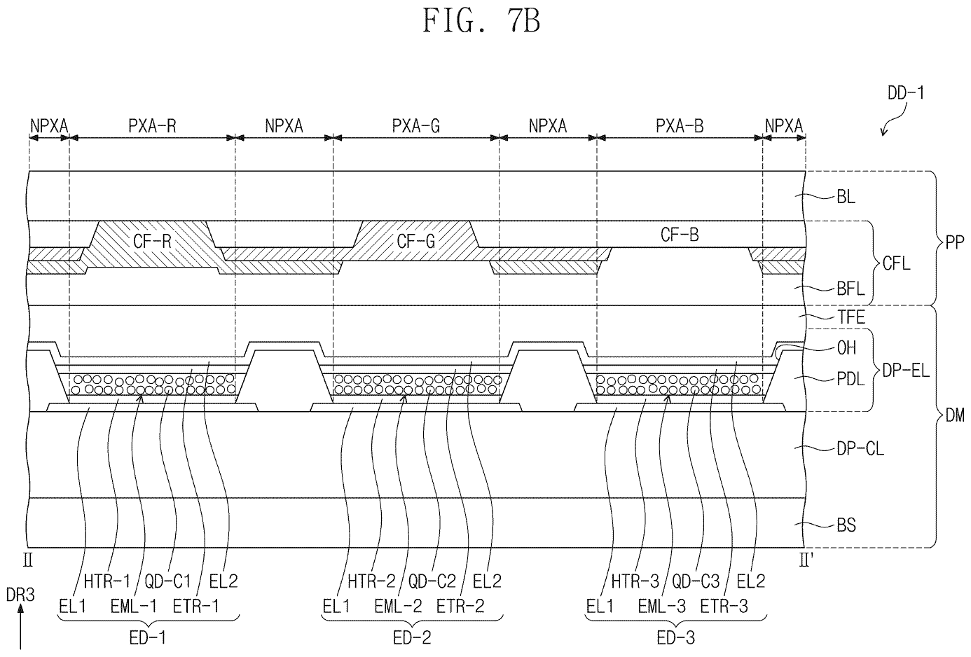

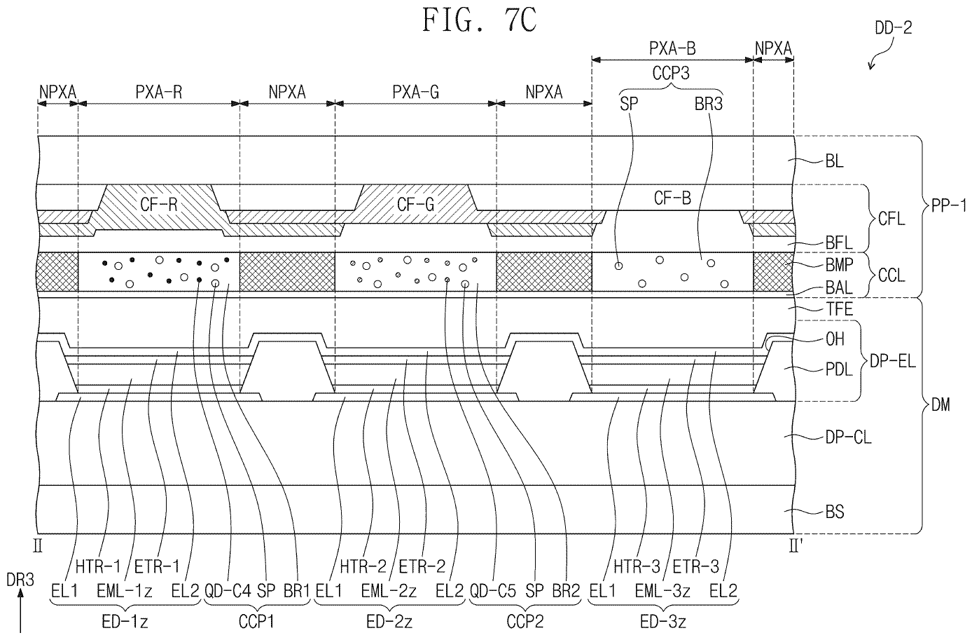

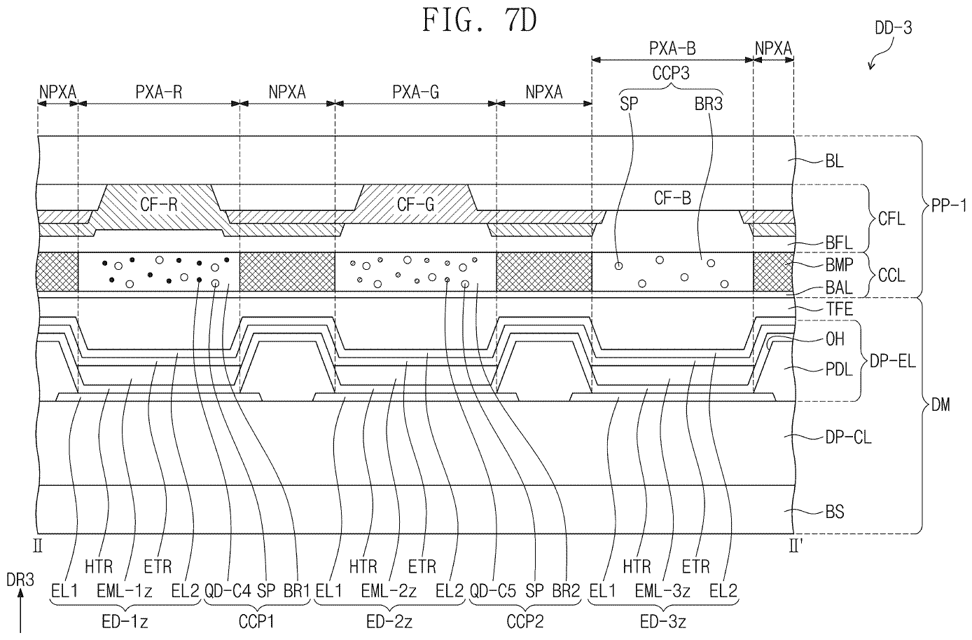

The active region DM-AA may be a region activated in response to an electrical signal. The active region DM-AA may include a pixel. The pixel may include a transistor and light-emitting elements ED-1 to ED-3, ED-1z to ED-3z (see FIG. 7A to FIG. 7D). The peripheral region DM-NAA may be located adjacent to at least one side of the active region DM-AA And may be a region arranged adjacent to at least one side of the active region DM-AA. In the peripheral region DM-NAA, a circuit, wirings, and/or the like for driving the active region DM-AA may be arranged.

FIG. 5 is a cross-section illustrating a portion taken along the line I-I′ in FIG. 4 according to one or more embodiments of the present disclosure. FIG. 5 may be a cross-sectional view illustrating a display device DD according to one or more embodiments.

The display device DD may include a display module DM and an optical layer PP arranged on the display module DM. The display module DM may include a base layer BS, a circuit layer DP-CL arranged on the base layer BS, a display element layer DP-EL arranged on the circuit layer DP-CL, and an encapsulation layer TFE arranged on the display element layer DP-EL. The display module DM may be also referred to as a display panel.

The display module DM may be a component which substantially generates an image. The display module DM may be a light-emitting-type (kind) display module. For example, in one or more embodiments, the display module DM may be a quantum dot light-emitting display module including a quantum dot light-emitting element. In one or more embodiments, the display module DM may be an organic light-emitting display module. The display module DM may be to emit source light.

The base layer BS may be a member that provides a base surface on which the circuit layer DP-CL is provided. The base layer BS may be a rigid substrate, or a flexible substrate that is bendable, foldable, or rollable. The base layer BS may be a glass substrate, a metal substrate, a polymer substrate, and/or the like. However, embodiments of the present disclosure are not limited thereto, and the base layer BS may be an inorganic layer, an organic layer, or a composite material layer.

The circuit layer DP-CL may be arranged on the base layer BS. The circuit layer DP-CL may include an insulation layer, a semiconductor pattern, a conductive pattern, a signal line, and/or the like. For example, in one or more embodiments, an insulation layer, a semiconductor layer, and a conductive layer, and/or the like are formed on the base layer BS through coating, deposition, and/or the like, and then the insulation layer, the semiconductor layer, and the conductive layer may be selectively patterned by performing a photolithography process multiple times. Thereafter, the semiconductor pattern, the conductive pattern, and the signal line included in the circuit layer DP-CL may be formed.

The display element layer DP-EL may be arranged on the circuit layer DP-CL. The display element layer DP-EL may include a pixel definition film PDL (see FIG. 7A to FIG. 7D), and first to third light-emitting elements ED-1 to ED-3, or ED-1z to ED-3z (see FIG. 7A to FIG. 7D). In the display module DM, the first to third light-emitting elements ED-1 to ED-3, or ED-1z to ED-3z (FIG. 7A to FIG. 7D) may be to emit source light. For example, the display element layer DP-EL may include an organic light-emitting material, an inorganic light-emitting material, an organic-inorganic light-emitting material, a quantum dot, and/or a quantum rod. For example, in one or more embodiments, the display element layer may include a micro-LED or a nano-LED.

The encapsulation layer TFE may protect the display element layer DP-EL from moisture, oxygen, and a foreign substance such as dust particles. The encapsulation layer TFE may include at least one inorganic layer. In one or more embodiments, the encapsulation layer TFE may include a structure in which an inorganic layer, an organic layer, and an inorganic layer are sequentially stacked.

The optical layer PP may be arranged on the display module DM and control reflected light of external light at the display module DM. The optical layer PP may be to transmit source light emitted from the display module DM and convert a wavelength of the source light. For example, in one or more embodiments, the optical layer PP may include a polarization layer or a color filter layer CFL (see FIG. 7A to FIG. 7C).

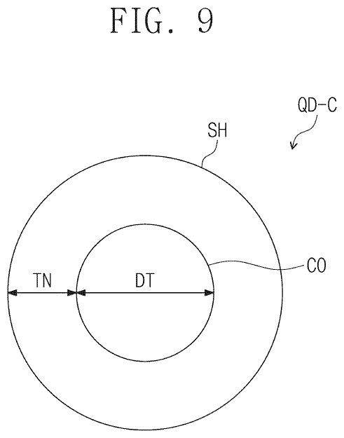

In one or more embodiments, the first to third light-emitting elements ED-1 to ED-3, or ED-1z to ED-3z (see FIG. 7A to FIG. 7D) or the optical layer PP may include a quantum dot QD-C (see FIG. 9) which will be described later. The electronic apparatus EA (FIG. 1) including the quantum dot QD-C (FIG. 9) according to one or more embodiments may exhibit excellent or suitable display quality.

In one or more embodiments, the display device DD may further include an input sensing layer arranged between the display module DM and the optical layer PP. The input sensing layer may detect an external input, convert the external input into a set input signal, and provide the input signal to the display module DM. For example, in one or more embodiments, the input sensing layer may be a touch sensing layer detecting a touch. The input sensing layer may recognize a direct touch provided by a user, an indirect touch provided by a user, a direct touch provided by an object, an indirect touch provided by an object, and/or the like.

The input sensing layer may detect at least one selected from among a touch position and touch intensity, applied from the outside. In one or more embodiments, the input sensing layer may have one or more suitable structures, or be composed of one or more suitable materials, but embodiments of the present disclosure are not limited thereto. For example, in one or more embodiments, the input sensing layer may detect external input in a capacitive manner. The display module DM may receive an input signal from the input sensing layer and generate an image corresponding to the input signal.

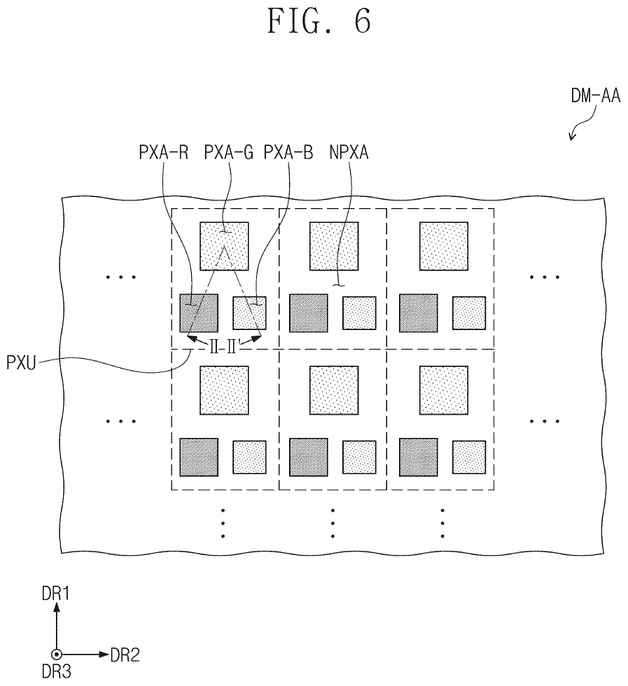

FIG. 6 is a plan view schematically illustrating the active region DM-AA according to one or more embodiments of the present disclosure. FIG. 6 illustrates a plane including three-pixel regions PXA-R, PXA-G, and PXA-B, and a light-blocking region NPXA as an example. In the active region DM-AA, unit pixels PXU may be arranged. The unit pixel PXU may include first to third pixel regions PXA-R, PXA-G, and PXA-B, and the light-blocking region NPXA. The unit pixels PXU may be repeatedly arranged throughout the active region DM-AA illustrated in FIG. 4.

The light-blocking region NPXA may be arranged around the first to third pixel regions PXA-R, PXA-G, and PXA-B. The light-blocking region NPXA may define boundaries of the first to third pixel regions PXA-R, PXA-G, and PXA-B. The light-blocking region NPXA may surround the first to third pixel regions PXA-R, PXA-G, and PXA-B. In the light-blocking region NPXA, a structure for preventing or reducing color mixing between the first to third pixel regions PXA-R, PXA-G, and PXA-B, for example, a pixel definition film PDL (see FIG. 7A to FIG. 7D) and/or the like, may be arranged.

The first to third pixel regions PXA-R, PXA-G, and PXA-B may be regions where light respectively generated from first to third light-emitting elements ED-1 to ED-3, or ED-1z to ED-3z (see FIG. 7A to FIG. 7D) is emitted. FIG. 6 illustrates that the first to third pixel regions PXA-R, PXA-G, and PXA-B have a same shape on a plane, and have different planar areas, but embodiments of the present disclosure are not limited thereto. For example, in one or more embodiments, at least two selected from pixel regions among the first to third pixel regions PXA-R, PXA-G, and PXA-B may have a same area. The areas of the first to third pixel regions PXA-R, PXA-G, and PXA-B may be individually set according to the color of their emitted light. In one or more embodiments, the pixel region emitting blue light among primary colors may have the smallest area. The area utilized herein may be a planar area.

FIG. 6 illustrates that the first to third pixel regions PXA-R, PXA-G, and PXA-B each have a quadrilateral shape on a plane. However, embodiments of the present disclosure are not limited thereto, for example, in one or more embodiments, the first to third pixel regions PXA-R, PXA-G, and PXA-B may each have another polygonal shape such as a rhombus or a pentagon. In one or more embodiments, the first to third pixel regions PXA-R, PXA-G, and PXA-B may each have a quadrilateral shape with a round corner region. In one or more embodiments, the first to third pixel regions PXA-R, PXA-G, and PXA-B may have different shapes on a plane.

FIG. 6 illustrates that the second pixel region PXA-G is arranged in a first row, and the first pixel region PXA-R and the third pixel region PXA-B are arranged in a second row. However, this is an example, and the arrangement of the first to third pixel regions PXA-R, PXA-G, and PXA-B may be variously modified. For example, in one or more embodiments, the first to third pixel regions PXA-R, PXA-G, and PXA-B may be arranged in a same row.

Any one region among the first to third pixel regions PXA-R, PXA-G, and PXA-B may be to emit first color light, another region may be to emit second color light which is different from the first color light, and the other region may be to emit third color light, which is different from the first color light and the second color light. For example, in one or more embodiments, the first pixel region PXA-R may be to emit red color light, the second pixel region PXA-G may be to emit green color light, and the third pixel region PXA-B may be to emit blue color light. The first pixel region PXA-R may be referred to as a red pixel region, the second pixel region PXA-G may be referred to as a green pixel region, and the third pixel region PXA-B may be referred to as a blue pixel region.

FIG. 7A is a cross-sectional view illustrating a portion taken along the line II-II′ in FIG. 6 according to one or more embodiments of the present disclosure. FIG. 7A may be a cross-sectional view illustrating in more detail a configuration of the display device DD according to one or more embodiments.

Referring to FIG. 7A, the base layer BS may include a single layer or a multilayer. For example, in one or more embodiments, the base layer BS may include a first synthetic resin layer, a multi-layered or single-layered inorganic layer, a second synthetic resin layer arranged on the multi-layered or single-layered inorganic layer. The first synthetic resin layer and the second synthetic resin layer may each include a polyimide-based resin layer. In addition, the first synthetic resin layer and the second synthetic resin layer may each include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In the present disclosure, the “~~” based resin indicates that a “~~” based functional group is included in the resin. For example, the polyimide-based resin indicates that a polyimide functional group is included in the resin.

The circuit layer DP-CL may include an insulation layer, a semiconductor layer, a conductive layer, and a signal line. In one or more embodiments, the circuit layer DP-CL may include a plurality of transistors. The transistors may each include a control electrode, an input electrode, and an output electrode. For example, the circuit layer DP-CL may include switching transistor(s) and driving transistor(s) for driving light-emitting elements ED-1, ED-2, and ED-3 of the display element layer DP-EL.

The display element layer DP-EL may include first to third light-emitting elements ED-1, ED-2, and ED-3 and a pixel definition film PDL. An opening OH may be defined in the pixel definition film PDL. The pixel definition film PDL may define first to third pixel regions PXA-R, PXA-G, and PXA-B. The first to third pixel regions PXA-R, PXA-G, and PXA-B, and the light-blocking region NPXA may be defined by the pixel definition film PDL.

The pixel definition film PDL may include a polymer resin. For example, in one or more embodiments, the pixel definition film PDL may include a polyacrylate-based resin or a polyimide-based resin. In one or more embodiments, the pixel definition film PDL may further include an inorganic material in addition to the polymer resin. In one or more embodiments, the pixel definition film PDL may include a light-absorbing material or may include a black pigment and/or a black dye. The pixel definition film PDL including the black pigment and/or the black dye may form a black pixel definition layer. In one or more embodiments, during the formation of the pixel definition film PDL, carbon black and/or the like may be used as the black pigment or black dye, but embodiments of the present disclosure are not limited thereto.

In one or more embodiments, the pixel definition film PDL may be formed of an inorganic material. For example, the pixel definition film PDL may be formed of an inorganic material such as silicon nitride (SiNₓ), silicon oxide (SiOₓ), and/or silicon oxynitride (SiOₓN_{y}).

Each of the first to third light-emitting elements ED-1, ED-2, and ED-3 may include a first electrode EL1, respective emission layer EML-1, EML-2, or EML-3 arranged on the first electrode EL1, a second electrode EL2 arranged on the emission layers EML-1, EML-2, and EML-3, and respective hole transport region HTR-1, HTR-2, or HTR-3 arranged between the first electrode EL1 and the second electrode EL2, and respective electron transport region ETR-1, ETR-2, or ETR-3 arranged between the first electrode EL1 and the second electrode EL2. The electron transport regions ETR-1, ETR-2, and ETR-3 may be spaced and/or apart (e.g., spaced apart or separated) from the corresponding hole transport regions HTR-1, HTR-2, and HTR-3 with respective emission layers EML-1, EML-2, and EML-3 therebetween. For example, the electron transport region ETR-1 may be spaced and/or apart (e.g., spaced apart or separated) from the hole transport region HTR-1 with the emission layer EML-1 therebetween, the electron transport region ETR-2 may be spaced and/or apart (e.g., spaced apart or separated) from the hole transport region HTR-2 with the emission layer EML-2 therebetween, and the electron transport region ETR-3 may be spaced and/or apart (e.g., spaced apart or separated) from the hole transport region HTR-3 with the emission layer EML-3 therebetween.

The first to third light-emitting elements ED-1, ED-2, and ED-3 may include a first electrode EL1, respective electron transport regions ETR-1, ETR-2, and ETR-3 arranged on the first electrode EL1, respective emission layers EML-1, EML-2, and EML-3 arranged on corresponding electron transport regions ETR-1, ETR-2, and ETR-3, respective hole transport regions HTR-1, HTR-2, and HTR-3 arranged on corresponding emission layers EML-1, EML-2, and EML-3, and a second electrode EL2 arranged on the hole transport regions HTR-1, HTR-2, and HTR-3. The electron transport regions ETR-1, ETR-2, and ETR-3 may be arranged between the first electrode EL1 and their corresponding emission layers EML-1, EML-2, and EML-3, and the hole transport regions HTR-1, HTR-2, and HTR-3 may be arranged between their corresponding emission layers EML-1, EML-2, and EML-3 and the second electrode EL2.

At least a portion of the first electrode EL1 may be exposed in the opening OH of the pixel definition film PDL. The first electrode EL1 may have conductivity (e.g., is an electron conductor). The first electrode EL1 may be formed of a metal material, a metal alloy, or a conductive compound. The first electrode EL1 may be a cathode or an anode. However, embodiments of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include indium tin oxide (ITO), indium zinc oxide (IZO), zinc oxide (ZnO), indium tin zinc oxide (ITZO), and/or the like. If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or a mixture thereof (for example, a mixture of Ag and Mg). In one or more embodiments, the first electrode EL1 may have a multi-layered structure which includes a reflective layer or transflective layer, formed of one or more of the above-described materials, and a transparent conductive layer formed of indium tin oxide (ITO), indium zinc oxide (IZO), zinc oxide (ZnO), indium tin zinc oxide (ITZO), and/or the like. For example, in one or more embodiments, the first electrode EL1 may have a three-layered structure of ITO/Ag/ITO, but embodiments of the present disclosure are not limited thereto. In one or more embodiments, the first electrode EL1 may include one of the above-described metal materials, a combination of two or more metal materials selected from among the above-described metal materials, or an oxide of the above-described metal material, but embodiments of the present disclosure are not limited thereto. The first electrode EL1 may have a thickness of about 700 angstroms (Å) to about 10000 Å.

For example, in one or more embodiments, the first electrode EL1 may have a thickness of about 1000 Å to about 3000 Å.

The second electrode EL2 may be a common electrode. The second electrode EL2 may be an anode or cathode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

The second electrode EL2 may be a transmissive electrode, a transflective electrode, or a reflective electrode. If (e.g., when) the second electrode EL2 is a transmissive electrode, the second electrode EL2 may be formed of a transparent metal oxide such as indium tin oxide (ITO), indium zinc oxide (IZO), zinc oxide (ZnO), and/or indium tin zinc oxide (ITZO).

If (e.g., when) the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or a mixture selected therefrom (for example, AgMg, AgYb, or MgYb). In one or more embodiments, the second electrode EL2 may have a multi-layered structure including a reflective layer or transflective layer formed of one or more of the above-described metal materials, and a transparent conductive layer formed of indium tin oxide (ITO), indium zinc oxide (IZO), zinc oxide (ZnO), indium tin zinc oxide (ITZO), and/or the like. For example, the second electrode EL2 may include one of the above-described metal materials, a combination of two or more selected from among the above-described metal materials, an oxide of the above-described metal materials, and/or the like.

In one or more embodiments, the second electrode EL2 may be connected to an auxiliary electrode. If (e.g., when) the second electrode EL2 is connected to the auxiliary electrode, the second electrode EL2 may have decreased resistance.

The emission layers EML-1, EML-2, and EML-3 may be each arranged between their corresponding first electrode EL1 and second electrode EL2. For example, the first light-emitting element ED-1 may include the first emission layer EML-1, the second light-emitting element ED-2 may include the second emission layer EML-2, and the third light-emitting element ED-3 may include the third emission layer EML-3. The first emission layer EML-1 may include a first quantum dot QD-C1. The second emission layer EML-2 may include a second quantum dot QD-C2. The third emission layer EML-3 may include a third quantum dot QD-C3. At least one among the first to third quantum dots QD-C1, QD-C2, and QD-C3 may be the quantum dot QD-C (FIG. 9) according to one or more embodiments of the present disclosure.

The quantum dots QD-C1, QD-C2, and QD-C3 respectively included in the emission layers EML-1, EML-2, EML-3 may each be stacked to form a layer. FIG. 7A illustrates that the quantum dots QD-C1, QD-C2, and QD-C3 each having a circular cross-section are arranged to form approximately two layers, but embodiments of the present disclosure are not limited thereto. For example, the arrangement of the quantum dots QD-C1, QD-C2, and QD-C3 may vary depending on thicknesses of their corresponding emission layers EML-1, EML-2, and EML-3, shapes of the quantum dots QD-C1, QD-C2, and QD-C3 included in the respective emission layers EML-1, EML-2, and EML-3, average diameters of the quantum dots QD-C1, QD-C2, and QD-C3, and/or the like. For example, in one or more embodiments, the quantum dots QD-C1, QD-C2, and QD-C3 may be arranged adjacent to each other in the respective emission layers EML-1, EML-2, and EML-3 to form a single layer or a plurality of layers such as two layers and three layers.

In one or more embodiments, the first light-emitting element ED-1 may be to emit red color light, the second light-emitting element ED-2 may be to emit green color light, and the third light-emitting element ED-3 may be to emit blue color light. Light emitted from the first to third light-emitting elements ED-1, ED-2, and ED-3 may be referred to as source light.

The first quantum dot QD-C1 of the first light-emitting element ED-1 may be to emit red color light. The second quantum dot QD-C2 of the second light-emitting element ED-2 may be to emit green color light. The third quantum dot QD-C3 of the third light-emitting element ED-3 may be to emit blue color light. For example, in one or more embodiments, the first to third quantum dots QD-C1, QD-C2, and QD-C3 may each include a core and a shell covering the core. The cores of the first to third quantum dots QD-C1, QD-C2, and QD-C3 may include different materials from one another. In one or more embodiments, any two cores among the cores of the first to third quantum dots QD-C1, QD-C2, and QD-C3 may include a same material, and the other one core may include a different material.

FIG. 7A illustrates that the first to third quantum dots QD-C1, QD-C2, and QD-C3 each have a similar diameter, but embodiments of the present disclosure are not limited thereto. The first to third quantum dots QD-C1, QD-C2, and QD-C3 may have different diameters. For example, the third quantum dot QD-C3 of the third light-emitting element ED-3, which emits light in a relatively short wavelength region, may have a relatively smaller average diameter than the first quantum dot QD-C1 of the first light-emitting element ED-1 and the second quantum dot QD-C2 of the second light-emitting element ED-2, each emitting light in a relatively long wavelength region. The average diameter is an arithmetic mean value of particle diameters of a plurality of quantum dots. The particle diameter of the quantum dot may be an average value of widths of quantum dot particles on a cross-section. Further, in the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

In one or more embodiments, the respective electron transport regions ETR-1, ETR-2, and ETR-3 of the first to third light-emitting elements ED-1, ED-2, and ED-3 may be arranged in the openings OH and separated from each other. In one or more embodiments, the respective electron transport regions ETR-1, ETR-2, and ETR-3 of the first to third light-emitting elements ED-1, ED-2, and ED-3 may also be provided as a common layer. The electron transport regions ETR-1, ETR-2, and ETR-3, provided as a common layer, may overlap the pixel regions PXA-R, PXA-G, and PXA-B and the light-blocking region NPXA. The first light-emitting element ED-1 may include the first electron transport region ETR-1, the second light-emitting element ED-2 may include the second electron transport region ETR-2, and the third light-emitting element ED-3 may include the third electron transport region ETR-3.

The first to third electron transport regions ETR-1, ETR-2, and ETR-3 may each have a single layer formed of a single material, a single layer formed of a plurality of different materials, or a multi-layered structure having a plurality of layers formed of a plurality of different materials. The first to third electron transport regions ETR-1, ETR-2, and ETR-3 may each have a thickness of, for example, about 1000 Å to about 1500 Å.

The first to third electron transport regions ETR-1, ETR-2, and ETR-3 may each include a suitable electron injection material and/or suitable electron transport material. For example, in one or more embodiments, the first to third electron transport regions ETR-1, ETR-2, and ETR-3 may include an anthracene-based compound. In one or more embodiments, the first to third electron transport regions ETR-1, ETR-2, and ETR-3 may each independently include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), or a mixture thereof. In one or more embodiments, the first to third electron transport regions ETR-1, ETR-2, and ETR-3 may each independently include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), and/or the like.

In one or more embodiments, the respective hole transport regions HTR-1, HTR-2, and HTR-3 of the first to third light-emitting elements ED-1, ED-2, and ED-3 may be arranged in the openings OH and separated from one another. In one or more embodiments, the respective hole transport regions HTR-1, HTR-2, and HTR-3 of the first to third light-emitting elements ED-1, ED-2, and ED-3 may be provided as a common layer. The hole transport regions HTR-1, HTR-2, and HTR-3, provided as a common layer, may overlap the pixel regions PXA-R, PXA-G, and PXA-B and the light-blocking region NPXA. The first light-emitting element ED-1 may include the first hole transport region HTR-1, the second light-emitting element ED-2 may include the second hole transport region HTR-2, and the third light-emitting element ED-3 may include the third hole transport region HTR-3.

The first to third hole transport regions HTR-1, HTR-2, and HTR-3 may each have a single layer formed of a single material, a single layer formed of a plurality of different materials, or a multi-layered structure having a plurality of layers formed of a plurality of different materials. The first to third hole transport regions HTR-1, HTR-2, and HTR-3 may each have a thickness of, for example, about 50 Å to about 15000 Å. In one or more embodiments, the first to third hole transport regions HTR-1, HTR-2, and HTR-3 may each have a thickness of about 100 Å to about 10000 Å, for example about 100 Å to about 5000 Å.

The first to third hole transport regions HTR-1, HTR-2, and HTR-3 may each independently include a suitable hole injection material and/or a suitable hole transport material. For example, in one or more embodiments, the first to third hole transport regions HTR-1, HTR-2, and HTR-3 may each independently include one or more selected from among a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalen-1-yl)-N,N′-diphenyl-benzidine (NPB), polyether ketone containing triphenylamine (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In one or more embodiments, the first to third hole transport regions HTR-1, HTR-2, and HTR-3 may each independently include one or more selected from among carbazole-based derivatives such as N-phenylcarbazole, and/or poly(N-vinylcarbazole), fluorene-based derivatives, triphenylamine-based derivatives such as N,N′-bis(3-methylphenyl)-N,N′-diphenyl-[1,1′-biphenyl]-4,4′-diamine (TPD), and/or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), and/or the like.

The encapsulation layer TFE may include at least one inorganic layer (hereinafter, referred to as an inorganic encapsulation layer). In one or more embodiments, the encapsulation layer TFE may include at least one organic layer (hereinafter, referred to as an organic encapsulation layer) and at least one inorganic layer.

The inorganic encapsulation layer may protect the display element layer DP-EL from moisture/oxygen, and the organic encapsulation layer may protect the display element layer DP-EL from foreign materials such as dust particles. The inorganic encapsulation layer may include silicon nitride, silicon oxynitride, silicon oxide, titanium oxide, aluminum oxide, and/or the like, but embodiments of the present disclosure are not particularly limited thereto. The organic encapsulation layer may include an acryl-based compound, an epoxy-based compound, and/or the like. In one or more embodiments, the organic encapsulation layer may include a photopolymerizable organic material but is not particularly limited thereto.

The optical layer PP may include a base substrate BL and a color filter layer CFL. The base substrate BL may be a member providing a base surface on which the color filter layer CFL is arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer.

In one or more embodiments, the color filter layer CFL may include first to third filters CF-R, CF-G, and CF-B. The first to third filters CF-R, CF-G, and CF-B may be arranged so as to correspond to the first to third light-emitting elements ED-1, ED-2, and ED-3, respectively. For example, in one or more embodiments, the first filter CF-R may be a red filter, the second filter CF-G may be a green filter, and the third filter CF-B may be a blue filter. The first to third filters CF-R, CF-G, and CF-B may be arranged corresponding to the first to third pixel regions PXA-R, PXA-G, PXA-B, respectively.

The first to third light-emitting elements ED-1, ED-2, and ED-3 may respectively include first to third quantum dots QD-C1, QD-C2, and QD-C3, and the color filter layer CFL in the optical layer PP may include a pigment and/or a dye. The first to third filters CF-R, CF-G, and CF-B may each include a polymer photosensitive resin and a pigment and/or a dye. In one or more embodiments, the first filter CF-R may include a red pigment and/or a red dye, the second filter CF-G may include a green pigment and/or a green dye, and the third filter CF-B may include a blue pigment and/or a blue dye. However, embodiments of the present disclosure are not limited thereto, for example, in one or more embodiments, the third filter CF-B may include no pigment or no dye. In one or more embodiments, the third filter CF-B may include a polymer photosensitive resin and include no pigment or no dye. The third filter CF-B may be transparent. In one or more embodiments, the third filter CF-B may be formed of a transparent photosensitive resin.

The color filter layer CFL may further include a buffer layer BFL. For example, the buffer layer BFL may be a protection layer protecting the first to third filters CF-R, CF-G, and CF-B. The buffer layer BFL may be arranged between the encapsulation layer TFE and the first to third filters CF-R, CF-G, and CF-B. The buffer layer BFL may include at least one inorganic layer. For example, in one or more embodiments, the buffer layer BFL may include an inorganic material. For example, the buffer layer BFL may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film that secures light transmittance, and/or the like. In one or more embodiments, the buffer layer BFL may further include an organic layer. The buffer layer BFL may be composed of a single layer or a plurality of layers.

In one or more embodiments, the first filter CF-R and the second filter CF-G may each be a yellow filter. In one or more embodiments, the first filter CF-R and the second filter CF-G may not be separated from each other and provided as one body.

In one or more embodiments, the color filter layer CFL may further include a light-blocking unit. The light-blocking unit may be a black matrix. The light-blocking unit may include an organic light-blocking material and/or inorganic light-blocking material, each of which includes a black pigment or a black dye. The light-blocking unit may prevent or reduce a light-leakage phenomenon and define boundaries between the adjacent filters CF-R, CF-G, and CF-B.

FIG. 7B to FIG. 7D are each a cross-sectional view illustrating a display device according to one or more embodiments of the present disclosure. In the following descriptions of FIG. 7B to FIG. 7D, the duplicated content with the details described with reference to FIG. 1 to FIG. 7A will not be described again for conciseness, and differences will be mainly described.

A display device DD-1 illustrated in FIG. 7B differs from the display device DD illustrated in FIG. 7A in arrangement positions of the electron transport regions ETR-1, ETR-2, and ETR-3 and the hole transport regions HTR-1, HTR-2, and HTR-3. Referring to FIG. 7B, the first to third light-emitting elements ED-1, ED-2, and ED-3 may each include a first electrode EL1, respective hole transport regions HTR-1, HTR-2, and HTR-3 arranged on the first electrode EL1, respective emission layers EML-1, EML-2, and EML-3 arranged on the corresponding hole transport regions HTR-1, HTR-2, and HTR-3, respective electron transport regions ETR-1, ETR-2, and ETR-3 arranged on the respective emission layers EML-1, EML-2, and EML-3, and a second electrode EL2 arranged on the electron transport regions ETR-1, ETR-2, and ETR-3. The electron transport regions ETR-1, ETR-2, and ETR-3 may be arranged between their corresponding emission layers EML-1, EML-2, and EML-3 and the second electrode EL2, and the hole transport regions HTR-1, HTR-2, and HTR-3 may be arranged between the first electrode EL1 and their corresponding emission layers EML-1, EML-2, and EML-3.

Display devices DD-2 and DD-3 illustrated in FIG. 7C and FIG. 7D, respectively, differ from the display device DD illustrated in FIG. 7A in that an optical layer PP-1 includes fourth and fifth quantum dots QD-C4 and QD-C5. In addition, the optical layer PP-1 illustrated in FIG. 7C and FIG. 7D differs from the optical layer PP illustrated in FIG. 7B in further including a light control layer CCL.

Referring to FIG. 7C, first to third light-emitting elements ED-1z, ED-2z, and ED-3z may respectively include first to third emission layers EML-1z, EML-2z, and EML-3z. The first to third emission layers EML-1z, EML-2z, and EML-3z may be separated by being arranged in an opening OH. In one or more embodiments, the first to third emission layers EML-1z, EML-2z, and EML-3z may be provided as a common layer and have an integrated shape. In one or more embodiments, the first emission layer EML-1z in the first light-emitting element ED-1z may include a fluorescent light-emitting material or a phosphorescent light-emitting material. The second emission layer EML-2z in the second light-emitting element ED-2z may include a fluorescent light-emitting material or a phosphorescent light-emitting material. The third emission layer EML-3z in the third light-emitting element ED-3z may include a fluorescent light-emitting material or a phosphorescent light-emitting material. The first to third emission layers EML-1z, EML-2z, and EML-3z may all be to emit blue light. However, this is an example, and light-emitting materials included in the first to third emission layers EML-1z, EML-2z, and EML-3z and emitted light are not limited thereto. For example, in one or more embodiments, the first emission layer EML-1z may be to emit red color light, the second emission layer EML-2z may be to emit green color light, and the third emission layer EML-3z may be to emit blue color light.

The light control layer CCL may be arranged between the encapsulation layer TFE and the color filter layer CFL. The light control layer CCL may include a photo-converter. The photo-converter may include the fourth and fifth quantum dots QD-C4 and QD-C5. The photo-converter may further include a phosphor and/or the like. The photo-converter may be to emit light by changing a wavelength of provided light. The light control layer CCL may include the fourth and fifth quantum dots QD-C4 and QD-C5 or include the fourth to fifth quantum dots QD-C4 and QD-C5, and a phosphor.

The light control layer CCL may include a plurality of light control units CCP1, CCP2, and CCP3. The light control units CCP1, CCP2, and CCP3 may be spaced and/or apart (e.g., spaced apart or separated) from one another in one direction perpendicular to a thickness direction DR3. In one or more embodiments, the light control layer CCL may further include a division pattern BMP arranged between the light control units CCP1, CCP2, and CCP3, spaced and/or apart (e.g., spaced apart or separated) from one another. The division pattern BMP may not overlap the light control units CCP1, CCP2, and CCP3. However, this is an example, in one or more embodiments, an edge of the light control units CCP1, CCP2, and CCP3 may overlap at least a portion of the division pattern BMP.

The light control layer CCL may include a first light control unit CCP1 including the fourth quantum dot QD-C4, a second light control unit CCP2 including the fifth quantum dot QD-C5, and a third light control unit CCP3 including no quantum dot. For example, in one or more embodiments, the fourth quantum dot QD-C4 may convert light emitted from the first light-emitting element ED-1z into red color light. The fifth quantum dot QD-C5 may convert light emitted from the second light-emitting element ED-2z into green color light. The third light control unit CCP3 may be to transmit light emitted from the third light-emitting element ED-3z. At least one selected from among the first and second light control units CCP1 and CCP2 may include the quantum dot QD-C (FIG. 9) according to one or more embodiments of the present disclosure. At least one selected from among the fourth quantum dot QD-C4 and the firth quantum dot QD-C5 may be the quantum dot QD-C (FIG. 9) according to one or more embodiments.

The light control layer CCL may further include a scatter SP. In one or more embodiments, the first light control unit CCP1 may include the fourth quantum dot QD-C4 and the scatter SP, the second light control unit CCP2 may include the fifth quantum dot QD-C5 and the scatter SP, and the third light control unit CCP3 may include no quantum dot and may include the scatter SP.

The scatter SP may be an inorganic particle. For example, the scatter SP may include any one selected from among TiO₂, ZnO, Al₂O₃, SiO₂, and a hollow silica, or may be a mixture of two or more selected from among TiO₂, ZnO, Al₂O₃, SiO₂, and a hollow silica.

The first light control unit CCP1, the second light control unit CCP2, and the third light control unit CCP3 may include the quantum dots QD-C4 and QD-C5, and base resins BR1, BR2, and BR3 dispersing the scatter SP. For example, in one or more embodiments, the first light control unit CCP1 may include the fourth quantum dot QD-C4 and the scatter SP, each dispersed in a first base resin BR1, the second light control unit CCP2 may include the fifth quantum dot QD-C5 and the scatter SP, each dispersed in a second base resin BR2, and the third light control unit CCP3 may include the scatter SP dispersed in a third base resin BR3.

The base resins BR1, BR2, and BR3 are each a medium in which the quantum dots QD1 and QD2 and the scatter SP are dispersed, accordingly, and may be formed of one or more suitable resin compositions which may be generally referred to as a binder. For example, the base resins BR1, BR2, and BR3 may each independently be an acryl-based resin, a urethane-based resin, a silicon-based resin, an epoxy-based resin, and/or the like. The base resins BR1, BR2, and BR3 may be transparent. The first base resin BR1, the second base resin BR2, and the third base resin BR3 may be the same, or at least one thereof may be different.

In one or more embodiments, the light control layer CCL may further include a barrier layer BAL. The barrier layer BAL may serve to prevent or reduce moisture and/or oxygen (hereinafter, referred to as ‘moisture/oxygen’) from permeating. The barrier layer BAL is arranged on the light control units CCP1, CCP2, and CCP3 and may block the light control units CCP1, CCP2, and CCP3 from being exposed to moisture/oxygen. The barrier layer BAL may cover the light control units CCP1, CCP2, and CCP3.

The barrier layer BAL may include at least one inorganic layer. For example, the barrier layer BAL may include an inorganic material. For example, the barrier layer BAL may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film that secures light transmittance, and/or the like. In one or more embodiments, the barrier layer BAL may further include an organic layer. The barrier layer BAL may be formed of a single layer, or a plurality of layers.

The display device DD-3 illustrated in FIG. 7D differs from the display device DD-2 illustrated in FIG. 7C in that the hole transport region HTR and the electron transport region ETR are each arranged as a common layer. Referring to FIG. 7D, the hole transport region HTR may be provided as a common layer in the first to third light-emitting elements ED-1z, ED-2z, and ED-3z. The hole transport region HTR may overlap the first to third pixel regions PXA-R, PXA-G, and PXA-B, and the light-blocking region NPXA. The electron transport region ETR may be provided as a common layer in the first to third light-emitting elements ED-1z, ED-2z, and ED-3z. The details described with reference to the above-described first to third hole transport regions HTR-1, HTR-2, and HTR-3 (FIG. 7A) will be similarly applied to the hole transport region HTR. The details described with reference to the above-described first to third electron transport regions ETR-1, ETR-2, and ETR-3 (FIG. 7A) will be similarly applied to the electron transport region ETR.

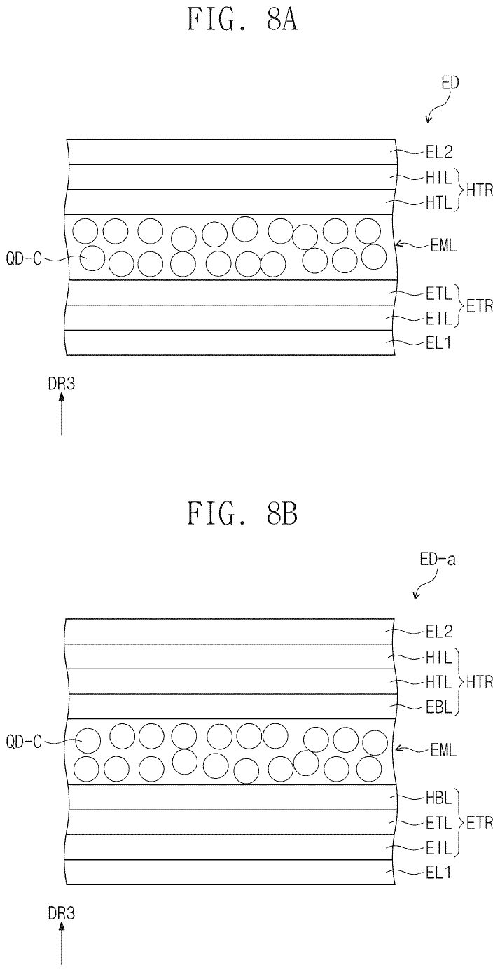

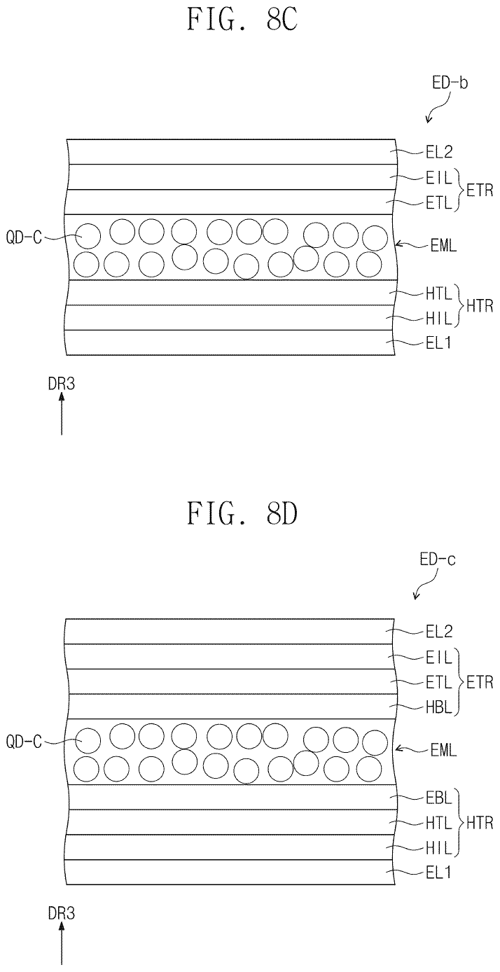

FIG. 8A to FIG. 8D are cross-sectional views respectively illustrating light-emitting elements ED, ED-a, ED-b, and ED-c according to one or more embodiments of the present disclosure. Referring to FIG. 8A to FIG. 8D, the light-emitting elements ED, ED-a, ED-b, and ED-c may each include a first electrode EL1, an emission layer EML arranged on the first electrode EL1, a second electrode EL2 arranged on the emission layer EML, a hole transport region HTR arranged between the first electrode EL1 and the second electrode EL2, and an electron transport region ETR arranged between the first electrode EL1 and the second electrode EL2. The electron transport region ETR may be spaced and/or apart (e.g., spaced apart or separated) from the hole transport region HTR with the emission layer EML therebetween. The emission layer EML may include the quantum dot QD-C according to an embodiment.

At least one selected from among the light-emitting elements ED and ED-a, which will be described with reference to FIG. 8A and FIG. 8B, will be similarly applied to at least one selected from among the first to third light-emitting elements ED-1, ED-2, and ED-3 illustrated in FIG. 7A. At least one selected from among the light-emitting elements ED-b and ED-c, which will be described with reference to FIG. 8C and FIG. 8D, may be similarly applied to at least one selected from among the first to third light-emitting elements ED-1, ED-2, and ED-3 illustrated in FIG. 7B. In addition, at least one selected from among the light-emitting elements ED-b and ED-c, which will be described with reference to FIG. 8C and FIG. 8D, may be similarly applied to at least one selected from among the first to third light-emitting elements ED-1z, ED-2z, and ED-3z illustrated in FIG. 7C and FIG. 7D except for including a quantum dot.

Referring to FIG. 8A and FIG. 8B, the light-emitting elements ED and ED-a may each include a first electrode EL1, an electron transport region ETR, an emission layer EML, a hole transport region HTR, and a second electrode EL2, which are sequentially stacked in the stated order. The electron transport region ETR may include an electron injection layer EIL and an electron transport layer ETL arranged on the electron injection layer EIL. The hole transport region HTR may include a hole transport layer HTL and a hole injection layer arranged on the hole transport layer HTL.

In the light-emitting element ED-a illustrated in FIG. 8B, the electron transport region ETR may further include a hole blocking layer HBL arranged between the electron transport layer ETL and the emission layer EML. The hole transport region HTR may further include an electron blocking layer EBL arranged between the emission layer EML and the hole transport layer HTL.

Referring to FIG. 8C and FIG. 8D, the light-emitting elements ED-b and ED-c may each include a first electrode EL1, a hole transport region HTR, an emission layer EML, an electron transport region ETR, and a second electrode EL2. The electron transport region ETR may include an electron transport layer ETL and an electron injection layer EIL arranged on the electron transport layer ETL. The hole transport region HTR may include a hole injection layer HIL and a hole transport layer HTL arranged on the hole injection layer HIL.

In the light-emitting element ED-c illustrated in FIG. 8D, the hole transport region HTR may further include an electron blocking layer EBL arranged between the hole transport layer HTL and the emission layer EML. The electron transport region ETR may further include a hole blocking layer HBL arranged between the emission layer EML and the electron transport layer ETL.

Unlike what is illustrated in FIG. 8A to FIG. 8D, in one or more embodiments, any one selected from among the electron injection layer EIL and the electron transport layer ETL may not be provided. Any one selected from among the hole injection layer HIL and the hole transport layer HTL may not be provided.

FIG. 9 is a view schematically illustrating a quantum dot according to one or more embodiments of the present disclosure. The details of the quantum dot QD-C according to one or more embodiments may be similarly applied to at least one selected from among the above-described first to third quantum dots QD-C1, QD-C2, and QD-C3 (FIG. 7A and FIG. 7B). For example, at least one selected from among the first and second quantum dots QD-C1, and QD-C2 may be the quantum dot QD-C according to one or more embodiments. The details of the quantum dot QD-C according to one or more embodiments may be similarly applied to at least one selected from among the above-described fourth and fifth quantum dots QD-C4 and QD-C5 (FIG. 7C and FIG. 7D). In the present disclosure, the quantum dot QD-C may refer to a crystal of a semiconductor compound.

Referring to FIG. 9, the quantum dot QD-C may include a core CO and a shell SH covering the core CO. In one or more embodiments, the quantum dot QD-C may further include a ligand. The ligand may eliminate a defect and/or the like of the core CO and the shell SH and may increase stability of the quantum dot QD-C.

For example, the ligand may include an organic ligand and/or a metal halide. The ligand may include at least one selected from among octadecane, octadecene, methanethiol, ethanethiol, propanethiol, butanethiol, pentanethiol, hexanethiol, octanethiol, dodecanethiol, hexadecanethiol, octadecanethiol, benzyl thiol, methane amine (methyl amine), ethane amine (ethyl amine), propane amine (propyl amine), butyl amine, pentyl amine, hexyl amine, octyl amine, dodecyl amine, hexadecyl amine, octadecyl amine, dimethyl amine, diethyl amine, dipropyl amine, oleyl amine, trioctylamine, methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyl diphenyl phosphine, trioctyl phosphine, trimethyl phosphine oxide, methyldiphenyl phosphine oxide, triethyl phosphine oxide, ethyldiphenyl phosphine oxide, and trioctyl phosphine oxide. However, this is an example, and any suitable ligand material in the related technical field may be included as a ligand without limitation.

In one or more embodiments, the core may include a multi-component system compound including copper (Cu), indium (In), gallium (Ga), and sulfur (S). Hereinafter, the “multi-component system compound including Cu, In, Ga, and S” refers to as a “CIGS compound”.

The core CO including the CIGS compound may have an absorption wavelength of about 350 nm to about 530 nm. The core CO including the CIGS compound may exhibit high absorption rate for light in a wavelength region of about 350 nm to about 530 nm. For example, the core CO may be to emit green color light or red color light by absorbing light (e.g., blue light) in a wavelength region of about 350 nm to about 530 nm. A wavelength of light emitted from the quantum dot QD-C may vary by adjusting the size of the core CO, the thickness of the shell SH, and/or the like.

In the quantum dot QD-C according to one or more embodiments, a diameter DT of the core CO may be about 2 nm to about 10 nm. The diameter DT of the core CO may be a width value of the core CO on a cross-section. In the quantum dot QD-C according to one or more embodiments, a thickness TN of the shell SH may be about 0.02 nm to about 10 nm.

The quantum dot QD-C according to one or more embodiments may have a peak emission wavelength in a wavelength region of about 520 nm to about 640 nm. The peak emission wavelength may refer to a wavelength at a point where light-emitting intensity is a highest in a light-emitting spectrum. The quantum dot QD-C according to one or more embodiments may have a full width at half maximum of about 41 nm or less. The quantum dot QD-C according to one or more embodiments may have a quantum yield of about 85% or more. The quantum dot QD-C according to one or more embodiments having the full width at half maximum of about 41 nm or less may be to emit light having high color purity. The quantum dot QD-C having the quantum yield of about 85% or more, according to one or more embodiments, may exhibit excellent or suitable light-emitting efficiency.

In one or more embodiments, moles of a first core component may be about 0.2 times to about 0.5 times moles of a second core component. The first core component may be Cu of the CIGS component. The second core component may be In and Ga of the CIGS component. Moles of Cu may be about 0.2 times to about 0.5 times a sum of moles of In and moles of Ga. The core CO in which the moles of the first core component is about 0.2 times to about 0.5 times the moles of the second core component may have the quantum yield of about 10% or more, and the full width at half maximum of about 40 nm or less. If (e.g., when) the moles of the first core component are less than about 0.2 times the moles of the second core component, the quantum yield of the core may be less than about 10%. If (e.g., when) the moles of the first core component are more than about 0.5 times the moles of the second core component, the full width at half maximum of the core may be more than about 40 nm.

In the core CO, moles of Ga may be about 0.05 times to about 20 times moles of In. The core CO in which the moles of Ga falls within about 0.05 times to about 20 times the moles of In may have a full width at half maximum may be about 40 nm or less, and a quantum yield of about 10% or more. The core in which the moles of Ga is more than about 20 times the moles of In may not emit light.

In the quantum dot QD-C manufactured by a method for manufacturing a quantum dot according to one or more embodiments, which will be described later, the core CO may have a concentration gradient for In and Ga. The core CO may be differentiated into an outer region and a central region spaced and/or apart (e.g., spaced apart or separated) from the shell SH with the outer region therebetween. A content (e.g., amount) of In may increase from the outer region toward the central region. A content (e.g., amount) of Ga may increase from the central region toward the outer region. For example, the content (e.g., amount) of In may be relatively high at the central region of the core CO, and the content (e.g., amount) of Ga may may be relatively high at the outer region of the core CO. In this regard, the content (e.g., amount) may be based on moles.

The shell SH effectively passivates a defect present on a surface of the core CO, and thus the quantum yield and stability of the quantum dot QD-C may increase. The shell SH according to one or more embodiments may include ZnS. The quantum dot QD-C including the shell SH that includes ZnS may exhibit high material stability for UV light. The shell SH includes ZnS which has a higher band gap than a band gap of the core CO and thus may contribute to improvements in efficiency and stability of the quantum dot QD-C.

In one or more embodiments, the shell SH may further include an oxide of metal or non-metal, a semiconductor compound, a combination thereof, and/or the like. Examples of the oxide of metal or non-metal may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; ternary compounds such as MgAl₂O₄, CoFe₂O₄, NiFe₂O₄, and/or CoMn₂O₄; or any combination thereof. Examples the semiconductor compound may include: a group III-VI semiconductor compound; a group II-VI semiconductor compound; a group III-V semiconductor compound; a group I-III-VI semiconductor compound; a group IV-VI semiconductor compound; or any combination thereof. For example, the semiconductor compound may include ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

Each element contained in multi-element compounds such as the binary compound, the ternary compound, and the quaternary compound may be present at a substantially uniform concentration or non-uniform concentration in a particle. For example, the formulas above may represent types (kinds) of elements included in the compound, and an element ratio in the compound may vary.

In the quantum dot QD-C, the moles of Zn of the shell SH may be about 1 time to about 5 times the moles of Cu of the core CO. For example, the moles of Zn may be about 1 time to about 5 times the moles of Cu. The quantum dot QD-C formed of Cu and Zn, where the moles of Zn are about 1 time to about 5 times the moles of Cu, may have a full width at half maximum of about 41 nm or less, and a quantum yield of about 85% or more. If (e.g., when) the moles of Zn are about 1 time to about 5 times the moles of Cu, efficiency and/or material stability of the quantum dot QD-C may enhance.

The following descriptions will be applied to the quantum dot that is not the quantum dot QD-C according to one or more embodiments of the present disclosure among first to fifth quantum dots QD-C1 to QD-C5 (FIG. 7A to FIG. 7D). Hereinafter, for convenience of explanation, the quantum dot that is not the quantum dot QD-C according to one or more embodiments is referred to as a ‘sub quantum dot’.

The quantum dots, e.g., sub quantum dots, may be to emit light with one or more suitable light-emitting wavelengths depending on the size of crystal thereof. A diameter of sub quantum dot may be, for example, about 1 nm to about 10 nm.

The sub quantum dot may be synthesized through a wet chemical process, an organic metal chemical vapor deposition process, a molecular beam epitaxy process, similar processes thereto, and/or the like. The wet chemical process is a method of mixing an organic solvent and a precursor material of a quantum dot and then growing a crystal of a quantum dot particle. When the crystal grows, the organic solvent may naturally serve as a dispersant that is coordinated to the surface of the quantum dot crystal and may control the growth of the crystal. Therefore, the wet chemical process may control the growth of the quantum dot particle through a simpler and more cost-effective process than a vapor deposition method such as metal organic chemical vapor deposition (MOCVD) or molecular beam epitaxy (MBE).

The sub quantum dot may include a group II-VI semiconductor compound, a group I-II-VI semiconductor compound, a group II-IV-VI compound, a group I-II-IV-VI semiconductor compound, a group III-V semiconductor compound, a group III-VI semiconductor compound, a group I-III-VI semiconductor compound, a group IV-VI semiconductor compound, a group II-IV-V semiconductor compound, a group IV element or compound, or any combination thereof. In the present disclosure, the term “group” refers to a group of the Periodic Table of Elements of the International Union of Pure and Applied Chemistry (“IUPAC”).

Non-limiting examples of the group II-VI semiconductor compound may include: binary compounds such as ZnS, ZnSe, ZnTe, ZnO, HgS, HgSe, HgTe, MgSe, and/or MgS; ternary compounds such as ZnSeS, ZnSeTe, ZnSTe, HgSeS, HgSeTe, HgSTe, HgZnS, HgZnSe, HgZnTe, MgZnSe, and/or MgZnS; quaternary compounds such as HgZnSeS, HgZnSeTe, and/or HgZnSTe; or any combination thereof.

The group II-VI semiconductor compound may further include a group I metal and/or a group IV element. The group I-II-VI compound may be selected from among CuSnS and CuZnS, and ZnSnS and/or the like may be selected as the II-IV-VI compound. The group I-II-IV-VI compound may be selected from among quaternary compounds selected from the group consisting of Cu₂ZnSnS₂, Cu₂ZnSnS₄, Cu₂ZnSnSe₄, Ag₂ZnSnS₂ and a mixture thereof.

Non-limiting examples of the III-V semiconductor compound may include: binary compounds such as GaN, GaP, GaAs, GaSb, AlN, AlP, AlAs, AlSb, InN, InP, InAs, and/or InSb; ternary compounds such as GaNP, GaNAs, GaNSb, GaPAs, GaPSb, AlNP, AlNAs, AlNSb, AIPAs, AlPSb, InGaP, InNP, InAlP, InNAs, InNSb, InPAs, and/or InPSb; quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. The group III-V semiconductor compound may further include a group II element. Non-limiting examples of the group III-V semiconductor compound further including the group II element may include InZnP, InGaZnP, InAlZnP, and/or the like.

Non-limiting examples of the group III-VI semiconductor compound may include: binary compounds such as GaS, Ga₂S₃, GaSe, Ga₂Se₃, GaTe, InS, InSe, In₂Se₃, and/or InTe; ternary compounds such as InGaS₃ and/or InGaSe₃; or any combination thereof.

Non-limiting examples of the group I-III-VI semiconductor compound may include: ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂; quaternary compounds such as AgInGaS₂ and/or AgInGaSe₂; or any combination thereof.

Non-limiting examples of the group IV-VI semiconductor compound may include: binary compounds such as SnS, SnSe, SnTe, PbS, PbSe, and/or PbTe; ternary compounds such as SnSeS, SnSeTe, SnSTe, PbSeS, PbSeTe, PbSTe, SnPbS, SnPbSe, and/or SnPbTe; quaternary compounds such as SnPbSSe, SnPbSeTe, and/or SnPbSTe; or any combination thereof.

Non-limiting examples of the group II-IV-V semiconductor compound may include ternary compounds selected from the group consisting of ZnSnP, ZnSnP₂, ZnSnAs₂, ZnGeP₂, ZnGeAs₂, and a mixture thereof.

Non-limiting examples of the group IV element or compound may include: a single-element compound such as Si or Ge; binary compounds such as SiC or SiGe; or any combination thereof.

Each element contained in a multi-component system compound such as the binary compound, the ternary compound, and the quaternary compound may be present in particles at a substantially uniform concentration or non-uniform concentration. For example, the formulas above may refer to types (kinds) of elements included in the compound, and element ratios in the compounds may be different. For example, AgInGaS₂ may refer to AgInₓGa₁₋ₓS₂ (where x is a real number between 0 to 1).

The sub quantum dot may have a single structure in which a concentration of each element included in the corresponding quantum dot is substantially uniform or a core-shell dual structure. For example, a material included in the core may be different from a material included in the shell.

The shell of the sub quantum dot may serve as a protection layer for preventing or reducing the core from being chemically modified to maintain semiconductor properties and/or as a charging layer for imparting electrophoretic properties to the quantum dot. The shell may have a single layer or a multilayer. In one or more embodiments, the core/shell structure may have a concentration gradient in which a concentration of elements present in the shell decreases toward the core.

Examples of the shell of the sub quantum dot may include an oxide of metal or non-metal, a semiconductor compound, a combination thereof, and/or the like. The details described with reference to the shell SH may be similarly applied to the examples of the oxide of metal or non-metal, the semiconductor compound, or a combination thereof.

The sub quantum dot may have a full width at half maximum (FWHM) of about 45 nm or less, for example, about 40 nm or less, for example, about 30 nm or less in the light-emitting spectrum, and if (e.g., when) the full width at half maximum of the sub quantum dot falls within the above-described range, color purity or color reproductivity of the sub quantum dot may be improved. In addition, light emitted through such a sub quantum dot is emitted in all directions, and thus an optical viewing angle may be improved. In addition, the shape of the sub quantum dot may be, for example, a shape of spherical nanoparticle, pyramidal nanoparticle, multi-arm nanoparticle, cubic nanoparticle, nanotube, nanowire, nanofiber, nanoplate particle, and/or the like.

An energy band gap of the sub quantum dot may be controlled or selected by controlling the sizes of the sub quantum dot or by controlling the element ratio in the compound constituting the sub quantum dot, and thus light with one or more suitable wavelength bands may be emitted in the emission layer EML which includes the sub quantum dot. Therefore, light-emitting elements ED, ED-a, ED-b, ED-c (FIG. 8A to FIG. 8D) emitting light with one or more suitable wavelengths may be implemented by using such a sub quantum dot (e.g., using quantum dots having different sizes or different element ratios in a quantum dot compound). For example, in one or more embodiments, the size of the sub quantum dots and/or the element ratio in the compound constituting the sub quantum dot may be selected such that red, green, and/or blue light is emitted. In addition, the sub quantum dots may be configured to emit white light by combining one or more suitable colors of light.

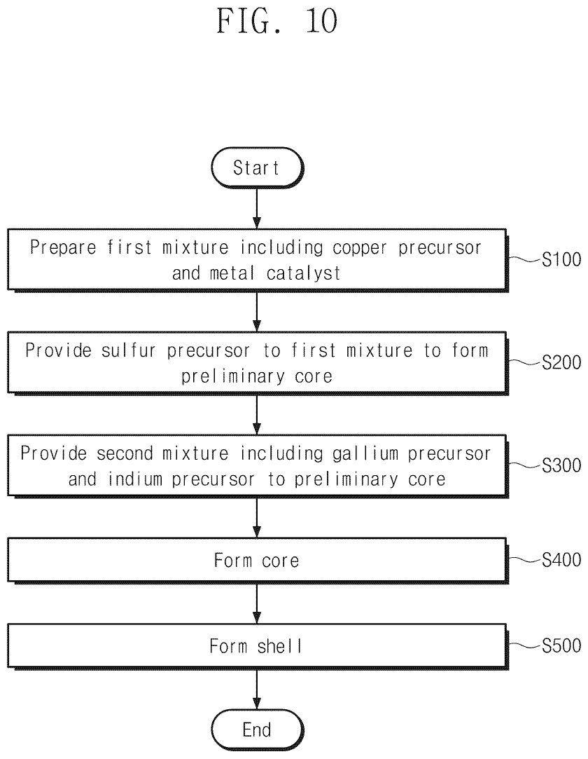

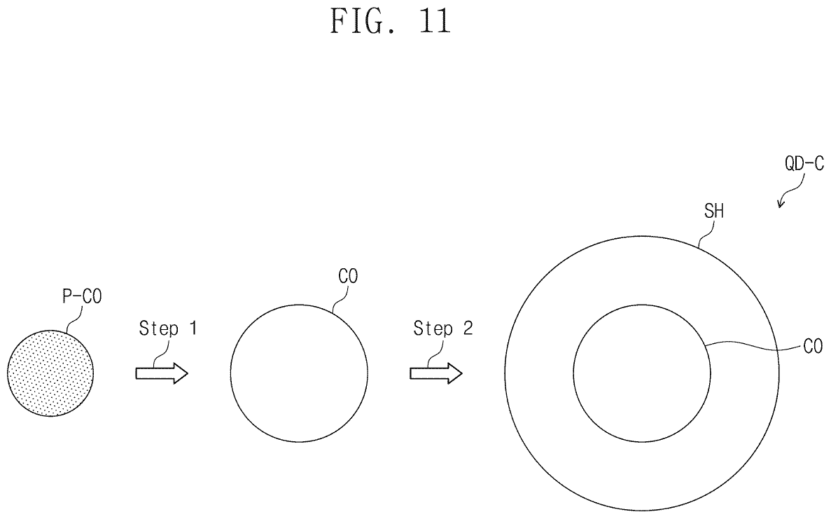

The quantum dot according to one or more embodiments may be manufactured by a method for manufacturing a quantum dot according to one or more embodiments of the present disclosure. FIG. 10 is a flow chart showing the method for manufacturing a quantum dot according to one or more embodiments. FIG. 11 is a diagram schematically showing steps (e.g., acts or tasks) of the method for manufacturing a quantum dot according to one or more embodiments. Hereinafter, duplicated details as the details described with reference to FIG. 1 to FIG. 9 will not be explained again, and differences will be mainly described.

Referring to FIG. 10, the method for manufacturing a quantum dot according to one or more embodiments may include: preparing a first mixture including a copper precursor and a metal catalyst (S100); providing a sulfur precursor (i.e., first sulfur precursor) to the first mixture to form a preliminary core (S200); providing a second mixture including a gallium precursor and an indium precursor to the preliminary core (S300); forming a core (S400); and forming a shell (S500). The providing of the second mixture to the preliminary core (S300) may be performed at a first temperature, and the forming of the core (S400) may be performed at a second temperature. The second temperature may be higher than the first temperature.

In the present disclosure, a metal precursor may be a material which includes a metal and a component chemically bonded to the metal, and the chemically bonded component may refer to a component which is easily dissociable from the metal. For example, in one or more embodiments, the metal precursor may be provided as a type (kind) of salt. The metal of metal precursor may be a component included in the quantum dot QD-C according to one or more embodiments. The metal may be copper, indium, gallium, sulfur, zinc, and/or the like.

The first mixture may include a copper precursor and a metal catalyst. The first mixture may include no gallium precursor and no indium precursor. In other words, the first mixture may exclude any gallium precursor and indium precursor The gallium precursor and the indium precursor may be provided separately from the copper precursor. In one or more embodiments, the first mixture may be degassed at about 120° C. for about 30 minutes. However, this is an example, and the temperature at and time for which the first mixture is degassed is not limited thereto.

The first mixture may further include a first solvent in which the copper precursor and the metal catalyst are dissolved. For example, the first solvent may be at least one selected from among hexane, toluene, chloroform, dimethyl sulfoxide, cyclohexylbenzene, hexadecane, and dimethyl formamide. However, this is an example, and embodiments of the present disclosure are not limited thereto.

In the first mixture, the copper precursor may include copper powder, copper halide, copper sulfate, copper acetylacetonate, copper hydroxide, copper oxide, copper nitrate, copper carboxylate, an alkylated copper compound, or a combination thereof. For example, in one or more embodiments, the copper precursor may include at least one selected from among copper halide, copper acetate, and copper nitrate.

The metal catalyst may include at least one first component selected from among Ag, Au, Li, Na, and K. The metal catalyst may be provided as an additive and may be provided in an extremely small amount. The first component of metal catalyst may be a metal and may be a group 1 element in the periodic table. The metal catalyst may further include a second component bonded to the first component. The second component may include a halogen element and oleate. For example, in one or more embodiments, the metal catalyst may include at least one selected from among AgI, AuCl, Na-oleate, NaCl, and KCl.

The first sulfur precursor may be provided to the first mixture, and thus a preliminary core P-CO illustrated in FIG. 11 may be formed. In one or more embodiments, the first sulfur precursor may be provided to the first mixture and the preliminary core P-CO may be formed at about 100° C. or more. However, this is an example, and the temperature at which the preliminary core P-CO is formed is not limited thereto.

The preliminary core P-CO may be formed by chemically reacting the copper precursor with the first sulfur precursor. The first sulfur precursor may include sulfur powder, sulfur halide, sulfur sulfate, sulfur acetylacetonate, sulfur hydroxide, sulfur oxide, sulfur nitrate, sulfur carboxylate, an alkylated sulfur compound, or a combination thereof. For example, the first sulfur precursor may include at least one selected from among sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis(trimethylsilyl) sulfide.

The metal catalyst may increase reactivity of the copper precursor and the first sulfur precursor. In addition, the metal catalyst may increase reactivity of the preliminary core P-CO, the gallium precursor, and the indium precursor. If (e.g., when) the metal catalyst is provided, it may be easy to form the core CO with the resolved surface defect. Accordingly, the quantum dot QD-C having excellent or suitable particle uniformity, full width at half maximum, and quantum yield may be formed from the preliminary core P-CO. The excellent or suitable particle uniformity may refer to that a plurality of quantum dots QD-C formed from a plurality of preliminary cores P-CO exhibit the substantially uniform size, the substantially uniform properties (for example, a full width at half maximum), and/or the like.

The preliminary core P-CO may include a multi-component system compound that includes Cu and S. Hereinafter, the “multi-component system compound including Cu and S” is referred to as a “CuS compound”. The CuS compound included in the preliminary core P-CO may be a seed for forming a core CO including the CIGS compound. The core CO including the CIGS compound may be grown from the preliminary core P-CO including the CuS compound, which is the seed.

The core Co may be formed by providing the second mixture into the preliminary core P-CO. The second mixture may include the gallium precursor and the indium precursor. In one or more embodiments, the second mixture may be degassed at about 120° C. for about 30 minutes before providing the second mixture to the preliminary core P-CO. However, this is an example, and the temperature and the time for degassing of the second mixture is not limited thereto.

In the second mixture, the gallium precursor may include gallium powder, gallium halide, gallium sulfate, gallium acetylacetonate, gallium hydroxide, gallium oxide, gallium nitrate, gallium carboxylate, an alkylated gallium compound, or a combination thereof. For example, the gallium precursor may include at least one selected from among gallium nitride, gallium phosphide, gallium (III) chloride, gallium (III) acetylacetonate, gallium (III) bromide, gallium (III) chloride, gallium (III) fluoride, gallium (III) iodide, gallium (III) nitrate hydrate, gallium (III) sulfate, and gallium (III) sulfate hydrate.

In the second mixture, the indium precursor may include indium powder, indium halide, indium sulfate, indium acetylacetonate, indium hydroxide, indium oxide, indium nitrate, indium carboxylate, an alkylated indium compound, or a combination thereof. For example, the indium precursor may include at least one selected from among indium (III) acetylacetonate, indium (III) bromide, indium (III) chloride, indium (III) fluoride, indium (III) iodide, indium (III) acetate, trimethyl indium, alkyl indium, aryl indium, indium (III) myristate, indium (III) myristate acetate, and indium (III) di-myristate acetate. Aryl is an aryl group and refers to a functional group or substituent derived from an aromatic hydrocarbon ring. The aryl group may be a monocyclic or polycyclic aryl group. The number of ring-forming carbon atoms of the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quarterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

The second mixture may be provided to the preliminary core P-CO at the first temperature, and the core CO may be formed at the second temperature. In FIG. 11, ‘Step 1’ shows the providing of the second mixture to the preliminary core P-CO to form the core CO. The core CO may be formed by reacting the preliminary core P-CO, the gallium precursor, and the indium precursor. The method for manufacturing a quantum dot according to one or more embodiments may further include cooling and purification between the forming of the core CO and the forming of the shell SH. For example, in one or more embodiments, the cooling and purification may be performed at a room temperature.

The second temperature is higher than the first temperature, and a third mixture including the preliminary core P-CO and the second mixture may be heated up to the second temperature. The second temperature may be about 230° C. to about 330° C. If (e.g., when) the second temperature is less than about 230° C., reactivity of the preliminary core, the gallium precursor and/or indium precursor is not sufficient, and thus no core may be formed. If (e.g., when) the second temperature is above about 330° C., materials may be destroyed (e.g., decomposed) because the temperature exceeding about 330° C. is an extremely high temperature.

The first mixture and the second mixture may each include at least one selected from among oleylamine, 1-octadecene, octadecane, methanethiol, ethanethiol, propanethiol, butanethiol, pentanethiol, hexanethiol, octanethiol, hexadecanethiol, benzylthiol, methane amine (methylamine), ethane amine (ethylamine), propane amine (propylamine), butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, and trioctyl phosphine oxide. For example, in one or more embodiments, the first mixture may further include oleylamine and 1-octadecene. The second mixture may further include oleylamine and 1-octadecene.

The first core component (that is, Cu) and the second core component (that is, In and Ga) are each an element from a different group in the periodic table and may have different reactivities. In the method for manufacturing a quantum dot according to one or more embodiments, the providing of the first core component and the second core component, each having different reactivity, may be separated. In the method for manufacturing a quantum dot according to one or more embodiments, the first mixture may be provided as a source of the first core component, and the second mixture may be provided as a source of the second core component. The first core component may react with the first sulfur precursor to form the preliminary core P-CO, and then may react with the second core component. For example, in one embodiment, the copper precursor in the first mixture may react with the first sulfur precursor to form a preliminary core, and then the gallium and indium precursors in the second mixture may be introduced at the first temperature to continue core growth, followed by heating to a higher second temperature to complete the core formation. This sequential approach allows each component—having different reactivities—to be incorporated in a controlled manner, resulting in a multi-component core with a desired composition and uniformity before forming the shell.

Each provided amount of the copper precursor, the gallium precursor, and the indium precursor may be provided such that the core CO, of which moles of the above-described first core component fall within about 0.2 times to about 0.5 times the moles of the second core component, is formed. In addition, each provided amount of the indium precursor and the gallium precursor may be provided such that the core CO, of which moles of Ga fall within about 0.05 times to about 20 times moles of the In, is formed. During the forming of the shell SH to be described later, a provided amount of the zinc precursor may be provided such that a quantum dot QD-C, of which the above-described moles of Zn is about 1 time to about 5 times moles of Cu, is formed.

The comparative method for manufacturing a quantum dot includes preparing one mixture of a copper precursor, a gallium precursor, and an indium precursor, providing a sulfur precursor to the mixture, and heating the resultant mixture to synthesize a core. When copper, indium, and gallium, having different reactivities are prepared as one mixture and are subjected to heating, it is difficult to secure uniformity of particles, and a quantum dot exhibiting a relatively large full width at half maximum and low quantum yield is manufactured. For example, the comparative method for manufacturing a quantum dot, in which a first core component and a second core component are not separately provided, exhibits low processibility, and the quantum dot manufactured by the method exhibits a full width at half maximum of more than about 41 nm and/or a quantum yield of less than about 85%.

In the present disclosure, the method for manufacturing a quantum dot according to one or more embodiments includes separately providing the first core component and the second core component, having different reactivities, and thus a quantum dot having excellent or suitable particle uniformity may be manufactured. Therefore, the method for manufacturing a quantum dot according to one or more embodiments may exhibit excellent or suitable processibility. The quantum dot manufactured according to the method for manufacturing a quantum dot according to one or more embodiments may have a full width at half maximum of about 41 nm or less, and quantum yield of about 85% or more.

Before the forming of the shell SH, the core CO may include the first component (e.g., the at least one first component) of the metal catalyst in an amount of less than about 3 mol % based on the total moles of the core CO. Before the forming of the shell SH, the core CO may include at least one selected from among Ag, Au, Li, Na, and K in an amount of less than about 3 mol %. After the forming of the shell SH, the first component of the metal catalyst may not be detected.

In one or more embodiments, before the forming of the shell SH, the core may have a full width at half maximum of about 41 nm or less. In one or more embodiments, before the forming of the shell SH, the core may have the full width at half maximum of about 40 nm or less. The core CO manufactured by the method for manufacturing a quantum dot according to one or more embodiments, which includes the providing of the metal catalyst, may exhibit a narrow full width at half maximum of about 41 nm or less.

The core CO may have a peak emission wavelength in a wavelength region of about 520 nm to about 640 nm, and a quantum yield thereof may be about 10% or more. The core having the full width half maximum of about 41 nm or less may be to emit light having high color purity. The core CO having the quantum yield of about 10% or more may exhibit excellent or suitable light-emitting efficiency. In one or more embodiments, before the forming of the shell SH, the core CO may have a peak emission wavelength in a wavelength region of about 520 nm to about 640 nm, a full width at half maximum of about 41 nm or less, and a quantum yield of about 10% or more.

In the method for manufacturing a quantum dot according to one or more embodiments, the forming of the shell SH may include providing a zinc precursor and a second sulfur precursor to the core CO and forming the shell at a temperature of about 200° C. or more. In FIG. 11, ‘Step 2’ shows the providing of the zinc precursor and the second sulfur precursor to the core CO, and the forming of a quantum dot QD-C including the shell SH.

The core CO, the zinc precursor, and the second sulfur precursor may be provided into a flask (i.e., reaction vessel). Before the providing of the core CO, the zinc precursor, and the second sulfur precursor, the flask may include a vacuum-treated trioctylamine. The core CO, the zinc precursor, and the second sulfur precursor may react to form a shell SH covering the core CO. Because reactivities of the core CO, the zinc precursor, and the second sulfur precursor are active at a temperature of about 200° C. or more, the temperature of about 200° C. or more may be suitable for the forming of a quantum dot QD-C including a core CO and a shell SH. For example, in one or more embodiments, the reaction during the forming of the shell SH may be performed at about 250° C. for about 20 minutes.

For example, the zinc precursor may include at least one selected from among Zn-oleate and ZnCl₂. The second sulfur precursor may be the same as or different from the first sulfur precursor. The second sulfur precursor may include sulfur powder, sulfur halide, sulfur sulfate, sulfur acetylacetonate, sulfur hydroxide, sulfur oxide, sulfur nitrate, sulfur carboxylate, an alkylated sulfur compound, or a combination thereof. For example, the second sulfur precursor may include at least one selected from among sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, and bis(trimethylsilyl) sulfide.

Hereinafter with reference to Examples and Comparative Examples, the method for manufacturing a quantum dot and a quantum dot, according to one or more embodiments of the disclosure, will be described in more detail. In addition, Examples shown herein are exemplified only for helping the understanding of the disclosure, and the scope of the disclosure is not limited thereto.

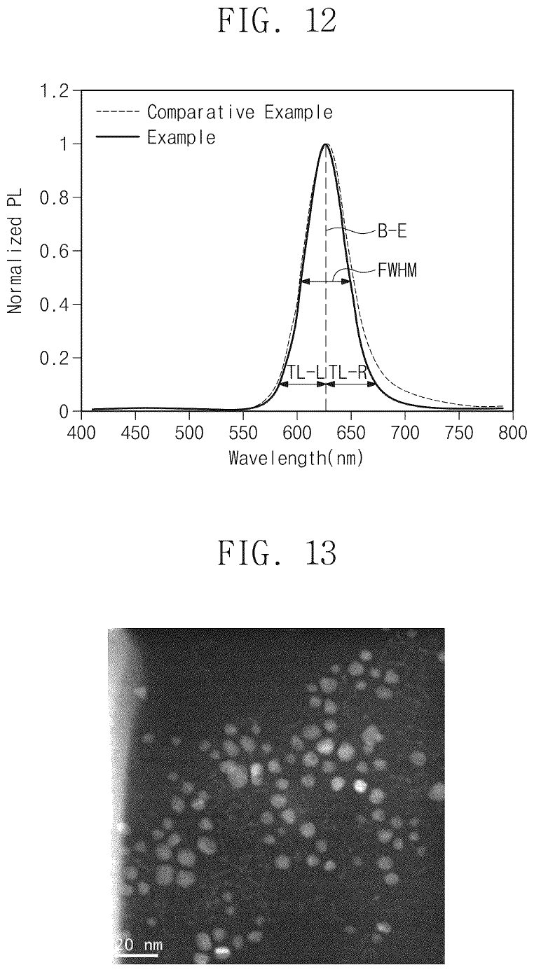

FIG. 12 is a graph showing photoluminescence (PL) depending on wavelengths in the cores according to Comparative Example and Example of the present disclosure, and PL is expressed in a normalized value. The graph in FIG. 12 was measured using FluoroMax PL spectroscopy made by HORIBA Scientific Ltd. The core according to Example was manufactured by the method for manufacturing a quantum dot according to one or more embodiments to be described later, wherein the core according to Example was manufactured by the method for manufacturing a core in the method for manufacturing a quantum dot according to one or more embodiments.

A first mixture was provided into a first flask and was subjected to degassing for about 120° C. for about 30 minutes. The first mixture included a copper precursor, a metal catalyst, oleylamine, and 1-octadecene, and the metal catalyst was AgI. Thereafter, a first sulfur precursor was provided into the first flask, and the resultant mixture was subjected to a reaction at about 100° C. or greater to form a preliminary core including a CuS Compound. A second mixture was provided into a second flask and was subjected to degassing at about 120° C. for about 30 minutes. The second mixture included a gallium precursor, an indium precursor, oleylamine, and 1-octadecene. The degassed second mixture was provided into the first flask, a reaction was performed at a high temperature of about 230° C. or more to form a core, and cooling and purification was performed. In the method for manufacturing, CuI was used as the copper precursor, Gals was used as the gallium precursor and InI₃ was used as the indium precursor. As the first sulfur precursor, yellow sulfur powder was used.

The core according to Comparative Example is manufactured by a manufacturing method to be described herein and includes no providing of a metal catalyst in the manufacturing method. During the manufacturing of the core according to Comparative Example, a mixture including a copper precursor, a gallium precursor, and an indium precursor are prepared and a first sulfur precursor is provided to the mixture to form a core. The manufacturing of the core according to Comparative Example differs from the manufacturing of the core according to Example in that the providing of the metal catalyst is not included and one mixture includes the copper precursor, the gallium precursor, and the indium precursor.

A mixture including a copper precursor, a gallium precursor, an indium precursor, oleylamine, and 1-octadecene was provided into a flask, and was subjected to degassing at about 120° C. for about 30 minutes. Thereafter, a reaction was performed by providing a first sulfur precursor at a temperature of about 100° C. or more and was maintained at a high temperature of about 230° C. or more into the flask, and cooling and purification were performed to obtain a core.

The following Table 1 exhibits an FWHM value and a tail value in the cores according to Comparative example and Example in FIG. 12. The tail value satisfies Equation 1.

$${T}_{3} = \vert {T}_{1} - {T}_{2} \vert \qquad Equation 1$$

In Equation 1, T₃ is a tail value and is an absolute value of T₁ minus T₂. T₁ is a half FWHM from a point at 1/10 of maximum light-emitting intensity value to a baseline, which is a right half FWHM, and corresponds to ‘TL-R’ illustrated in FIG. 12. T₂ is a half FWHM from a point at 1/10 of the maximum light-emitting intensity value to the baseline, which is a left half FWHM, and corresponds to ‘TL-L’ illustrated in FIG. 12. The baseline refers to a line extending parallel to a vertical axis from a wavelength at the point where the light-emitting intensity is maximum, and corresponds to ‘B-E’ illustrated in FIG. 12. In FIG. 12, the point at about 1/10 of the maximum light-emitting intensity value refers to a point where a vertical axis value is about 0.1. As the tail value is close to 0, it can be determined that the graph is highly left-right symmetric, and uniformity of particles are excellent or suitable. In Table 1, the light-emitting wavelength represents a peak emission wavelength.

TABLE 1

| | Light-emitting wavelength | FWHM | Tail |
|---|---|---|---|
| Comparative | 628 nm | 50 nm | 13 nm |
| Example | | | |
| Example | 624 nm | 38 nm | 8 nm |

Referring to Table 1, it can be seen that the core according to Comparative Example has a peak emission wavelength of about 628 nm, and the core according to Example has a peak emission wavelength of about 624 nm. Compared to the core according to Comparative Example, it can be seen that the core according to Example has a small FWHM value and a small tail value. Compared to the core according to Comparative Example, it can be seen that the core according to Example emits light having high color purity and exhibits excellent or suitable uniformity. As described above, the core according to Example is formed by providing the metal catalyst, and the providing of the first core component (that is, Cu) and the providing of the second core component (that is, In and Ga) are separated in the manufacturing method. Accordingly, it can be seen that the method for manufacturing a quantum dot according to one or more embodiments, which includes the providing of the first mixture including the copper precursor and the metal catalyst, and the providing of the second mixture including the gallium precursor and the indium precursor after the providing of the sulfur precursor (i.e., first sulfur precursor) to the first mixture, exhibits excellent or suitable processibility. It can be seen that the quantum dot manufactured by the method for manufacturing a quantum dot according to one or more embodiments emits light having high color purity and will exhibit excellent or suitable uniformity.

A light-emitting wavelength, a full width at half maximum, and a tail value of each core according to Comparative Example and Examples were measured and the measurement results are listed in the following Table 2. The light-emitting wavelength, the full width at half maximum, and the quantum yield were measured in each quantum dot according to Comparative Example and Examples and the measurement results are listed in the following Table 3. The results in Table 2 and Table 3 were measured using FluoroMax PL spectroscopy made by HORIBA Scientific Ltd. The quantum dot according to Comparative Example in Table 3 includes a core according to Comparative Example and a shell covering the core. The quantum dots according to Examples Q-1 to Q-5 in Table 3 include a core and a shell and respectively include cores according to Examples C-1 to C-5 as the cores in Table 2. QY in Table 3 represents a quantum yield.

The cores according to Comparative Example and Examples in Table 2 and Table 3 each include a CIGS compound. The core according to Comparative Example is the same as the core according to Comparative Example, described with reference to FIG. 12. For example, the core according to Comparative Example was formed without providing of the metal catalyst. The core according to Example C-1 is the same as the core according to Example, described with reference to FIG. 12. The cores according to Examples C-2 to C-5 were each manufactured by following substantially the same manufacturing steps of the method for manufacturing a core according to Example described with reference to FIG. 12 except for a provided metal catalyst. The cores according to Examples were each formed by providing the metal catalyst listed in Table 2. In Table 2, a light-emitting wavelength represents a peak emission wavelength, and a tail value satisfies Equation 1, described above.

In the quantum dots according to Comparative Example and Examples, the shell was formed by the following method. Trioctylamine was prepared into a flask by vacuum-treating, the core according to Comparative Example or Examples, a zinc precursor, a second sulfur precursor, and trioctyl phosphine were injected thereto. The resultant was heated to about 250° C. and was subjected to a reaction for about 20 minutes to obtain a quantum dot including a core and a shell. As the zinc precursor, Zn-oleate and ZnCl₂ were used, and the same material as the first sulfur precursor was used as the second sulfur precursor.

TABLE 2

| | | Light-emitting | Full width at | | |
|---|---|---|---|---|---|
| | Metal catalyst | wavelength | half maximum | Tail | |
| Comparative | — | 628 nm | 50 nm | 13 | nm |
| Example | | | | | |
| Example C-1 | AgI | 624 nm | 38 nm | 8 | nm |
| Example C-2 | AuCl | 632 nm | 39 nm | 8 | nm |
| Example C-3 | Na-oleate | 620 nm | 40 nm | 13 | nm |
| Example C-4 | NaCl | 619 nm | 40 nm | 6 | nm |
| Example C-5 | KCl | 618 nm | 40 nm | 6 | nm |

Referring to Table 2, it can be seen that the core according to Comparative Example exhibits a peak emission wavelength of about 628 nm, and the cores in Examples C-1 to C-5 each exhibit a peak emission wavelength of about 618 nm to about 632 nm. It can be seen that the cores according to Examples C-1 to C-5 each exhibit a smaller full width at half maximum and/or a smaller tail value than the core according to Comparative Example. It can be seen that the cores according to Examples C-1 to C-5, each have a full width at half maximum of about 40 nm or less.

It can be seen that the cores according to Experimental Examples C-1 to C-5 each emit light having high color purity and exhibit excellent or suitable uniformity. As described above, the cores according to Examples are each formed by providing the metal catalyst, and the providing of the first core component (that is, Cu) and the providing of the second core component (that is In and Ga) are separated in the manufacturing method. Therefore, it can be seen that the method for manufacturing a quantum dot according to one or more embodiments, which includes the providing of the first mixture including the copper precursor and the metal catalyst, and the providing of the second mixture including the gallium precursor and the indium precursor after the providing of the sulfur precursor to the first mixture, exhibit excellent or suitable processibility. The quantum dot manufactured according to the method for manufacturing a quantum dot according to one or more embodiments emits light having high color purity and exhibit excellent or suitable uniformity.

TABLE 3

| | | Light-emitting | Full width at | |
|---|---|---|---|---|
| | Metal catalyst | wavelength | half maximum | QY |
| Comparative | — | 632 nm | 49 nm | 87% |
| Example | | | | |
| Example Q-1 | AgI | 626 nm | 39 nm | 94% |
| Example Q-2 | AuCl | 630 nm | 40 nm | 91% |
| Example Q-3 | Na-oleate | 624 nm | 41 nm | 88% |
| Example Q-4 | NaCl | 622 nm | 41 nm | 87% |
| Example Q-5 | KCl | 620 nm | 41 nm | 85% |

Referring to Table 3, it can be seen that the quantum dot according to Comparative Example exhibits a peak emission wavelength of about 632 nm, and the quantum dots according to Examples Q-1 to Q-5 each exhibit a peak emission wavelength of about 618 nm to about 632 nm. It can be confirmed that the cores according to Examples Q-1 to Q-5 each exhibit a smaller full width at half maximum and/or higher quantum yield than the quantum dot according to Comparative Example. It can be seen that the cores according to Examples Q-1 to Q-5 each have a full width at half maximum of about 41 nm or less, and a quantum yield of about 85% or more. It can be seen that the cores according to Examples Q-1 to Q-5, each emit light having high color purity and exhibit excellent or suitable light-emitting efficiency. As described above, the quantum dots according to Examples are each formed by providing the metal catalyst, and the providing of the first core component (that is, Cu) and the providing of the second core component (that is In and Ga) are separated in the manufacturing method. Therefore, it can be seen that the method for manufacturing a quantum dot according to one or more embodiments, which includes the providing of the first mixture including the copper precursor and the metal catalyst and the providing of the gallium precursor and the indium precursor after the providing of the sulfur precursor to the first mixture, exhibits excellent or suitable processibility. It can be seen that the quantum dot manufactured according to the method for manufacturing a quantum dot according to one or more embodiments emits light having high color purity and exhibit excellent or suitable uniformity.

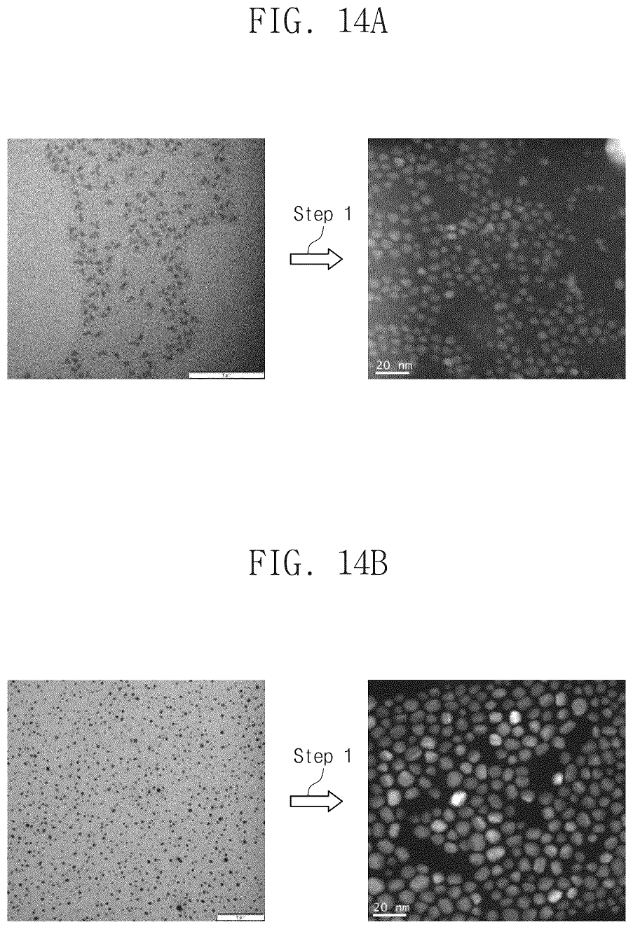

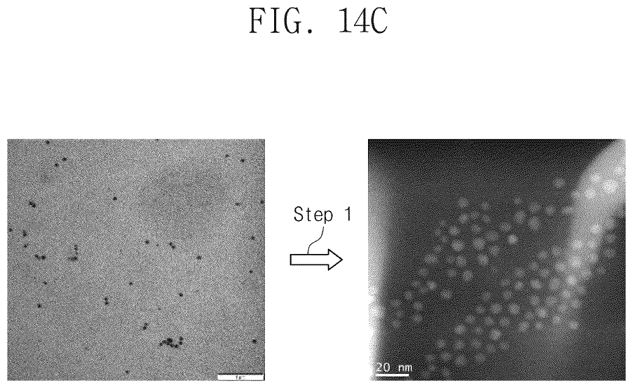

FIG. 13 is an image of the core manufactured by the method for manufacturing a core according to Comparative Example, as captured by a transmission electron microscope (TEM). FIG. 14A to FIG. 14C are each an image of the preliminary core and the core manufactured by the method for manufacturing a core according to Example, as captured by a transmission electron microscope (TEM). The cores in FIG. 13, and FIG. 14A to FIG. 14C each include a CIGS compound. The preliminary cores in FIG. 14A to FIG. 14C each include a CuS compound. The preliminary core and the core in FIG. 14A are provided with AuCl as the metal catalyst during the manufacturing. The preliminary core and the core in FIG. 14B are provided with AgI as the metal catalyst during the manufacturing. The preliminary core and the core in FIG. 14C are provided with Na-oleate as the metal catalyst during the manufacturing.

In FIG. 14A to FIG. 14C, ‘Step 1’ corresponds to ‘Step 1’ shown in FIG. 11. In each of FIG. 14A to FIG. 14C, the image on a left side based on Step 1 is a captured image of the preliminary core, and the image on a right side is a captured image of the core formed from the preliminary core.

Referring to the images on the right side of each of FIG. 14A to FIG. 14C, and FIG. 13, the cores according to Examples each have more excellent or suitable uniformity than the core according to Comparative Example. As described above, the cores according to Examples are each formed by providing the metal catalyst, and the providing of the first core component (that is, Cu) and the providing of the second core component (that is, In and Ga) are separated in the manufacturing method. Therefore, it can be seen that the method for manufacturing a quantum dot according to one or more embodiments including the providing of the first mixture including a copper precursor and a metal catalyst, and the providing of the second mixture including a gallium precursor and an indium precursor after the providing of a sulfur precursor to the first mixture exhibits excellent or suitable processibility. It can be seen that the quantum dot manufacture by the method for manufacturing a quantum dot according to one or more embodiments emits light having high color purity and exhibit excellent or suitable uniformity.

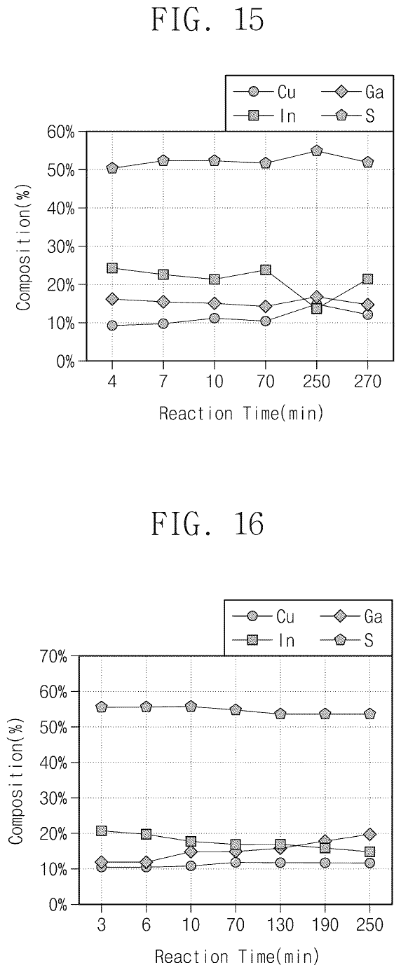

FIG. 15 exhibits a composition of the core according to Comparative Example depending on reaction time, and the composition is based on the number of moles. FIG. 16 exhibits a composition of the core according to Example depending on reaction time, and the composition is based on the number of moles. The cores according to Example and Comparative Example were each manufactured by the above-described respective manufacturing method. The reaction time refers to the time elapsed from the point at which the temperature reaches about 230° C. during the above-described manufacturing method. The compositions in FIG. 15 and FIG. 16 were analyzed by an inductively coupled plasma (ICP). The composition depending on the reaction time in FIG. 15 is listed in Table 4. The composition depending on the reaction time in FIG. 16 is listed in Table 5.

TABLE 4

| Reaction time (min) | Cu | In | Ga | S |
|---|---|---|---|---|
| 4 | 9% | 24% | 16% | 50% |
| 7 | 10% | 23% | 15% | 52% |
| 10 | 11% | 21% | 15% | 52% |
| 70 | 10% | 24% | 14% | 52% |
| 250 | 15% | 14% | 17% | 55% |
| 270 | 12% | 21% | 15% | 52% |

TABLE 5

| Reaction time (min) | Cu | In | Ga | S |
|---|---|---|---|---|
| 3 | 11% | 21% | 12% | 56% |
| 6 | 11% | 20% | 12% | 56% |
| 10 | 11% | 18% | 15% | 56% |
| 70 | 12% | 17% | 15% | 55% |
| 130 | 12% | 17% | 16% | 54% |
| 190 | 12% | 16% | 18% | 54% |
| 250 | 12% | 15% | 20% | 54% |

Referring to FIG. 15 and Table 4, the core according to Comparative Example has a substantially uniform distribution of the core compositions even as time passes. Referring to FIG. 16 and Table 5, it can be seen that, in the core according to Example, a distribution of each core composition has a concentration gradient. In the core according to Example, it can be seen that, when the reaction time reaches about 250 minutes, unlike what was observed for about 250 minutes, the composition of the In exhibits a smaller value than the Ga composition. Accordingly, it can be seen that the quantum dot formed by the method for manufacturing a quantum dot according to one or more embodiments exhibits a relatively high In content (e.g., amount) at a central region of the core and exhibits a relatively high Ga content (e.g., amount) at an outer region of the core.

The core according to Experimental Examples were evaluated, and the evaluated results are listed in Table 6. The values in Table 6 are evaluated using Ultima Expert Inductively Coupled Plasma-Optical Emission Spectrometry (ICP-OES) made by HORIBA Scientific Ltd.

In Table 6, a ‘molar ratio of introduced element’ represents molar ratios of elements (that is, Cu, In, and Sn) provided during the manufacturing of the core. The cores in Experimental Examples differ in the molar ratios of introduced elements. In Table 6, the ‘ICP molar ratio’ represents a ratio of the moles of the components of the manufactured core, as analyzed by an inductively coupled plasma (ICP), and “Cu/In+Ga” is a value of the moles of the first core component divided by the moles of the second core component. “Ga/In” is a value of the moles of Ga divided by the moles of In. A ‘light-emitting wavelength’ represents a peak emission wavelength. A tail value satisfies Equation 1, described previously, and a QY represents a quantum yield. In Table 6, the core in Experimental Example B-3 emits no light, and thus luminous properties cannot be evaluated.

TABLE 6

| | | | | Luminous characteristics | | | | | |
|---|---|---|---|---|---|---|---|---|---|
| | Molar ratio of | | | | Full | | | | |
| | introduced | | | Light- | width at | | | | |
| | element | | | emitting | half | | | ICP molar ratio | |
| | Cu | In | Ga | wavelength | maximum | Tail | QY | Cu/In + Ga | Ga/In |
| Experimental | 0.1 | 0.5 | 1.0 | 627 nm | 38 nm | 9 nm | 3% | 0.10 | 8.73 |
| Example B-1 | | | | | | | | | |
| Experimental | 0.15 | 0.5 | 1.0 | 625 nm | 39 nm | 10 nm | 15% | 0.21 | 10.7 |
| Example A-1 | | | | | | | | | |
| Experimental | 0.2 | 0.5 | 1.0 | 624 nm | 38 nm | 8 nm | 34% | 0.44 | 5.43 |
| Example A-2 | | | | | | | | | |
| Experimental | 0.4 | 0.5 | 1.0 | 636 nm | 56 nm | 23 nm | 46% | 0.56 | 1.84 |
| Example B-2 | | | | | | | | | |
| Experimental | 0.2 | 0.5 | 1.5 | — | — | — | <1% | 0.13 | 24.3 |
| Example B-3 | | | | | | | | | |

Referring to Table 6, it can be seen that the cores of Experimental Examples A-1 and A-2 each have a peak emission wavelength of about 520 nm to about 640 nm and a full width at half maximum of about 41 nm or less, and a quantum yield of about 10% or more. It can be seen that the cores of Experimental Examples A-1 and A-2 each exhibit a relatively small tail value. The moles of the first core component are about 0.2 times to about 0.5 times the moles of the second core component of in each core of Experimental Examples A-1 and A-2. In addition, the moles of Ga is about 0.05 times to about 20 times the moles of In in each core of Experimental Examples A-1 and A-2. Accordingly, it can be seen that the core of the quantum dot according to one or more embodiments including a core in which the moles of the first core component are about 0.2 times to about 0.5 times the second core component exhibits a full width at half maximum of about 41 nm or less, and a quantum yield of about 10% or more. It can be seen that the core of the quantum dot according to one or more embodiments including a core in which the moles of Ga are about 0.05 times to about 20 times the moles of In exhibits a full width at half maximum of about 41 nm or less, and a quantum yield of about 10% or more.

The core of Experimental Example B-1 has a quantum yield of less than about 10%. In the core of Experimental Example B-1, the moles of the first core component are about 0.1 times (that is, less than about 0.2 times) the moles of the second core component. Therefore, the core in Experimental Example B-1 exhibits a low quantum yield of less than about 10%.

The core of Experimental Example B-2 has a full width at half maximum of about 56 nm, and exhibits a relatively large tail value. The core of Experimental Example B-2 exhibiting the relatively large full width at half maximum and tail value emits light having deteriorated color purity. In the core of Experimental Example B-2, the moles of the first core component are about 0.56 times (that is, more than about 0.5 times) the moles of the second core component. Therefore, the core of Experimental Example B-2 exhibits the large full width at half maximum and the large tail value.

The core of Experimental Example B-3 has a quantum yield of less than about 1%, and thus emits no light. In the core of Experimental Example B-3, the moles of the first core component are about 0.13 times (that is, less than about 0.2 times) the moles of the second core component. Therefore, the core of Experimental Example B-3 emits no light.

The quantum dots of Experimental Examples were evaluated, and the evaluated results are listed in Table 7. The results in Table 7 were evaluated using Ultima Expert ICP-OES made by HORIBA Scientific Ltd. In Table 7, the details described with reference to Table 6 are similarly applied to a ‘light-emitting wavelength’, a ‘QY’, and ‘ICP molar ratio’. In Table 7, the ‘molar ratio of introduced element’ represents a molar ratio of the moles of Cu introduced during the forming of the Core and the moles of Zn introduced during forming of the shell.

TABLE 7

| | Molar | | | | | |
|---|---|---|---|---|---|---|
| | ratio of | | Luminous characteristics | | | ICP |
| | introduced | | Light- | Full width | | molar |
| | element | | emitting | at half | | ratio |
| | Cu | Zn | wavelength | maximum | QY | Zn/Cu |
| Experimental | 1 | 7 | 626 nm | 39 nm | 94% | 2.03 |
| Example X-1 | | | | | | |
| Experimental | 1 | 10 | 625 nm | 38 nm | 99% | 3.14 |
| Example X-2 | | | | | | |
| Experimental | 1 | 15 | 624 nm | 46 nm | 84% | 5.14 |
| Example Y-1 | | | | | | |

Referring to Table 7, the quantum dots in Experimental Examples X-1 and X-2 each have a peak emission wavelength of about 520 nm to about 640 nm, and a full width at half maximum of about 41 nm or less, and a quantum yield of about 85% or greater. The moles of Zn in each quantum dot of Experimental Examples X-1 and X-2 are about 1 time to about 5 times the moles of Cu. Therefore, it can be seen that the quantum dot according to one or more embodiments having the moles of Zn of about 1 time to about 5 times the moles of Cu exhibit a full width at half maximum of about 41 nm or less and a quantum yield of about 85% or greater.

It can be seen that the quantum dot in Experimental Example Y-1 has a full width at half maximum of about 46 nm (that is, more than about 41 nm) and a quantum yield of about 84% (that is, less than about 85%). In the quantum dot of Experimental Example Y-1, the moles of Zn are about 5.14 times (that is, more than about 5 times) the moles of Cu. Therefore, the quantum dot of Experimental Example Y-1 exhibits the large full width at half maximum and the low quantum yield.

The quantum dot manufacturing method according to one or more embodiments may include: forming a preliminary core by providing a sulfur precursor to a first mixture which includes a copper precursor and a metal catalyst; and forming a core by providing a second mixture to the preliminary core. After the providing of the second mixture, the resultant mixture may be subjected to heating. The second mixture may include a gallium precursor and an indium precursor. The quantum dot manufacturing method according to one or more embodiments in which the first core component (that is, Cu) and the second core component (that is, In, and Ga), having different reactivities, are separately provided, may exhibit excellent or suitable processibility. The quantum dot manufactured by the quantum dot manufacturing method according to one or more embodiments may be to emit light having good or suitable color purity and may exhibit excellent or suitable light-emitting efficiency. The electronic apparatus, including the quantum dot according to one or more embodiments, may exhibit excellent or suitable display quality and excellent or suitable reliability.

The method for manufacturing a quantum dot according to one or more embodiments includes providing a metal precursor material and a metal catalyst, and thus may exhibit excellent or suitable processibility.

The quantum dot according to one or more embodiments and the electronic apparatus including the same include metal components satisfying a molar ratio according to one or more embodiments, and thus may exhibit excellent or suitable efficiency. For example, by separating the introduction of the first core component (Cu) and the second core components (In and Ga) into distinct steps, the method allows each element—having different reactivities—to be incorporated under conditions favorable to its reaction. This sequential approach, combined with the utilization of a metal catalyst in the first mixture and subsequent heating after the second mixture is added, promotes uniform nucleation and controlled growth of the multi-component core. As a result, the manufactured quantum dot can achieve a precise composition ratio, leading to improved processability during synthesis and enhanced optical properties such as high emission efficiency and narrow full width at half maximum (FWHM). When integrated into an electronic apparatus, these quantum dots contribute to superior color purity, display quality, and long-term reliability.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

The light-emitting element, the display module, the display device, the electronic apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hitherto, although one or more embodiments of the present disclosure have been described with reference to example embodiments, those skilled in the art or having ordinary knowledge of the art will understand that one or more suitable modifications and changes may be made without departing from the technical idea or features of the present disclosure as provided in the appended claims.

Accordingly, the technical scope of the disclosure is not limited to what is set forth in the detailed description of the disclosure, but should be defined by the claims and equivalents thereof.

What is claimed is:

1. A method, comprising:
preparing a first mixture comprising a copper precursor and a metal catalyst;
providing a first sulfur precursor to the first mixture to form a preliminary core;
providing a second mixture comprising a gallium precursor and an indium precursor to the preliminary core at a first temperature;
forming a core at a second temperature higher than the first temperature; and
forming a shell covering the core,
wherein the metal catalyst comprises at least one first component selected from among Ag, Au, Li, Na, and K, and
wherein the method is a method for manufacturing a quantum dot comprising:
the core comprising a multi-component system compound containing Cu, In, Ga, and S; and
the shell covering the core.

2. The method of claim 1,
wherein the metal catalyst further comprises a second component chemically bonded to the first component, and
the second component further comprises at least one selected from among a halogen element and oleate.

3. The method of claim 1, wherein the core comprises the first component in an amount of less than 3 mol % with respect to the total moles of the core before the forming of the shell.

4. The method of claim 1, wherein the second temperature is 230° C. to 330° C.

5. The method of claim 1,
wherein the forming of the shell comprises:
providing a zinc precursor and a second sulfur precursor to the core; and
forming the shell at a temperature of 200° C. or more.

6. The method of claim 1,
wherein moles of a first core component are 0.2 times to 0.5 times moles of a second core component in the quantum dot, and
the first core component is the Cu, and the second core component is the In and the Ga.

7. The method of claim 1, wherein moles of the Ga are 0.05 times to 20 times moles of the In.

8. The method of claim 1, wherein the shell comprises ZnS, and
moles of the Zn of the shell are 1 time to 5 times moles of the Cu of the core.

9. The method of claim 1, wherein the quantum dot has a peak emission wavelength in a wavelength region of 520 nm to 640 nm, a full width at half maximum (FWHM) of 41 nm or less, and a quantum yield of 85% or more.

10. The method of claim 1,
wherein the copper precursor comprises at least one selected from among copper halide, copper acetate, and copper nitrate,
the first sulfur precursor comprises at least one selected from among sulfur-trioctylphosphine, sulfur-tributylphosphine, sulfur-triphenylphosphine, sulfur-oleylamine, sulfur-trioctylamine, sulfur-octadecene, sulfur-diphenylphosphine, sulfur-dodecylamine, octanethiol, dodecanethiol, octadecanethiol, α-toluenethiol, allyl mercaptan, and bis (trimethylsilyl) sulfide,
the indium precursor comprises at least one selected from among indium (III) acetylacetonate, indium (III) bromide, indium (III) chloride, indium (III) fluoride, indium (III) iodide, indium (III) acetate, trimethyl indium, alkyl indium, aryl indium, indium (III) myristate, indium (III) myristate acetate, and indium (III) di-myristate acetate,
the gallium precursor comprises at least one selected from among gallium nitride, gallium phosphide, gallium (III) chloride, gallium (III) acetylacetonate, gallium (III) bromide, gallium (III) chloride, gallium (III) fluoride, gallium (III) iodide, gallium (III) nitrate hydrate, gallium (III) sulfate, and gallium (III) sulfate hydrate, and
the first mixture and the second mixture each further comprises at least one selected from among oleylamine, 1-octadecene, octadecane, methanethiol, ethanethiol, propanethiol, butanethiol, pentanethiol, hexanethiol, octanethiol, hexadecanethiol, benzylthiol, methylamine, ethylamine, propylamine, butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, and trioctyl phosphine oxide.

11. The method of claim 1, wherein the core has a peak emission wavelength in a wavelength region of 520 nm to 640 nm, a full width at half maximum of 40 nm or less, and a quantum yield of 10% or more.

12. A quantum dot, comprising:
a core comprising a multi-component system compound containing Cu, In, Ga, and S; and
a shell covering the core,
wherein moles of a first core component are 0.2 times to 0.5 times moles of a second core component, and
wherein the first core component is the Cu and the second core component is the In and the Ga.

13. The quantum dot of claim 12,
wherein the core comprises an outer region and a central region, and the outer region is between the central region and the shell, and
wherein an amount of the In increases toward the central region from the outer region, and
an amount of the Ga increases from the central region toward the outer region.

14. The quantum dot of claim 12, wherein moles of the Ga are 0.05 times to 20 times moles of the In.

15. The quantum dot of claim 12,
wherein the quantum dot has a peak emission wavelength in a wavelength region of 520 nm to 640 nm, a full width at half maximum (FWHM) of 41 nm or less, and a quantum yield of 85% or more, and
the core has a diameter of 2 nm to 10 nm, and the shell has a thickness of 0.02 nm to 10 nm.

16. The quantum dot of claim 12,
wherein the shell comprises ZnS, and
moles of the Zn of the shell are 1 time to 5 times the moles of the Cu of the core.

17. An electronic apparatus comprising:
a display module comprising a light-emitting element configured to emit source light; and
an optical layer on the display module and configured to transmit the source light or to convert a wavelength of the source light,
wherein the light-emitting element or the optical layer comprises a quantum dot,
wherein the quantum dot comprises:
a core comprising a multi-component system compound comprising Cu, In, Ga, and S; and
a shell covering the core,
wherein moles of a first core component are 0.2 times to 0.5 times moles of a second core component, and
wherein the first core component is the Cu and the second core component is the In and the Ga.

18. The electronic apparatus of claim 17, wherein the quantum dot has a peak emission wavelength in a wavelength region of 520 nm to 640 nm, a full width at half maximum (FWHM) of 41 nm or less, and a quantum yield of 85% or more.

19. The electronic apparatus of claim 17,
wherein the optical layer comprises a first light control unit configured to convert a wavelength of the source light and a second light control unit configured to transmit the source light, and
the first light control unit comprises the quantum dot.

20. The electronic apparatus of claim 17,
wherein the light-emitting element comprises:
a first electrode;
a second electrode on the first electrode;
an emission layer between the first electrode and the second electrode and comprising the quantum dot;
a hole transport region between the first electrode and the second electrode; and
an electron transport region between the first electrode and the second electrode and spaced from the hole transport region, and
wherein the emission layer is between the hole transport region and the electron transport region.
